(19) United States
(12) Patent Application Publication
(10) Pub. No.: US 2026/0237351 A1
(43) Pub. Date: Aug. 13, 2026

(54) DISPLAY PANEL AND DISPLAY APPARATUS

(71) Applicants: CHONGQING BOE DISPLAY TECHNOLOGY CO., LTD., Chongqing (CN); BOE TECHNOLOGY GROUP CO., LTD., Beijing (CN)

(72) Inventors: Rui WANG, Beijing (CN); Shouqiang ZHANG, Beijing (CN); Runxin ZHANG, Beijing (CN); Liyuan XU, Beijing (CN); Hongtao WENG, Beijing (CN); Yuanyou QIU, Beijing (CN)

(21) Appl. No.: 19/148,038

(22) PCT Filed: Apr. 24, 2023
(86) PCT No.: PCT/CN2023/090226

§ 371 Date: Jul. 15, 2025

(51) Int. Cl. G09G 3/3241; H10K 59/121; H10K 59/126; H10K 59/131

(52) U.S. Cl. CPC G09G 3/3241; H10K 59/1213; H10K 59/126; H10K 59/1315; G09G 2300/0426; G09G 2300/0819; G09G 2320/0233; G09G 2320/0242; G09G 2330/021

(57) ABSTRACT

A display panel includes a pixel driving circuit, where the pixel driving circuit includes a second transistor and a driving transistor, a first electrode of the second transistor is connected to a gate of the driving transistor, and a second electrode of the second transistor is connected to a first electrode of the driving transistor. The display panel further includes: a base substrate; an active layer, located on a side of the base substrate; a first metal layer, located between the base substrate and the active layer; and a second metal layer, located on a side of the active layer away from the base substrate. The active layer includes a second active portion, configured to form a channel region of the second transistor; and a third active portion, connected to the second active portion, where the third active portion is configured to form a channel region of the driving transistor.

### TECHNICAL FIELD

The present disclosure relates to the field of display technology, and in particular to a display panel and a display device.

### BACKGROUND

Organic Light Emitting Diode (OLED) is an active light-emitting display device with the advantages of self-luminescence, wide viewing angle, high contrast, low power consumption, extremely high response speed, lightness, flexibility and so on. Currently, OLED display screens are increasingly widely used. In related art, OLED display screens have the problem of color deviation under strong light.

It should be noted that the information disclosed in this background section is only used to enhance understanding the background of the present disclosure, and therefore may include information that does not constitute the prior art known to those skilled in the art.

### SUMMARY

The purpose of the present disclosure is to overcome the above-mentioned deficiencies of the prior art and provide a display panel and a display device.

According to an aspect of the present disclosure, a display panel is provided and includes a plurality of pixel driving circuits, where the pixel driving circuit includes a second transistor and a driving transistor, a first electrode of the second transistor is connected to a gate of the driving transistor, and a second electrode of the second transistor is connected to a first electrode of the driving transistor; where the display panel further includes: a base substrate; an active layer, located on a side of the base substrate, where the active layer includes: a second active portion configured to form a channel region of the second transistor, and a third active portion connected to the second active portion and configured to form a channel region of the driving transistor; a first metal layer, located between the base substrate and the active layer; and a second metal layer, located on a side of the active layer away from the base substrate. Orthographic projections of both the first metal layer and the second metal layer on the base substrate at least partially overlap with orthographic projections of the second active portion and the third active portion on the base substrate.

In some embodiments of the present disclosure, the first metal layer is connected to a constant voltage source; the second active portion includes a first active sub-portion and a second active sub-portion. The active layer further includes: a ninth active portion, connected between the first active sub-portion and the second active sub-portion; where the orthographic projection of the first metal layer on the base substrate overlaps with the orthographic projections of the second active portion and the third active portion on the base substrate, and does not overlap with an orthographic projection of the ninth active portion on the base substrate.

In some embodiments of the present disclosure, the display panel includes a plurality of the pixel driving circuits, the first metal layer includes a plurality of shielding units, with each of the shielding units corresponding to one of the pixel driving circuits. The shielding unit includes: a first shielding portion, arranged corresponding to the second active portion, where the first shielding portion has a notch, an orthographic projection of the first shielding portion on the base substrate overlaps with the orthographic projection of the second active portion on the base substrate, and the orthographic projection of the ninth active portion on the base substrate is located within an orthographic projection of the notch on the base substrate; and a second shielding portion, arranged corresponding to the third active portion and connected to the first shielding portion, where an orthographic projection of the second shielding portion on the base substrate overlaps with the orthographic projection of the third active portion on the base substrate.

In some embodiments of the present disclosure, the first metal layer is connected to a constant voltage source; the display panel includes a plurality of the pixel driving circuits, the first metal layer includes a plurality of shielding units, with each of the shielding units corresponding to one of the pixel driving circuits. The shielding unit includes: a second shielding portion, arranged corresponding to the third active portion and connected to a first shielding portion, where an orthographic projection of the second shielding portion on the base substrate overlaps with the orthographic projection of the third active portion on the base substrate. The display panel further includes: a first conductive layer, located on the side of the active layer away from the base substrate, and the first conductive layer includes: a first conductive block, configured to form the gate of the driving transistor, where an orthographic projection of the first conductive block on the base substrate covers the orthographic projection of the third active portion on the base substrate and overlaps with the orthographic projection of the second shielding portion on the base substrate.

In some embodiments of the present disclosure, the orthographic projection of the first conductive block on the base substrate covers the orthographic projection of the second shielding portion on the base substrate.

In some embodiments of the present disclosure, the orthographic projection of the first conductive block on the base substrate coincides with the orthographic projection of the second shielding portion on the base substrate.

In some embodiments of the present disclosure, the first metal layer is connected to a constant voltage source; the display panel includes a plurality of the pixel driving circuits, the first metal layer includes a plurality of shielding units, with each of the shielding units corresponding to one of the pixel driving circuits. The shielding unit includes: a first shielding portion, arranged corresponding to the second active portion, where the first shielding portion has a notch, an orthographic projection of the first shielding portion on the base substrate overlaps with the orthographic projection of the second active portion on the base substrate, and an orthographic projection of the a ninth active portion on the base substrate is located within an orthographic projection of the notch on the base substrate; a second shielding portion, arranged corresponding to the third active portion and connected to the first shielding portion, where an orthographic projection of the second shielding portion on the base substrate overlaps with the orthographic projection of the third active portion on the base substrate; a first connecting portion, connected to the first shielding portion, where an orthographic projection of the first connecting portion on the base substrate extends along a column direction; a second connecting portion, connected to a side, in the column direction, of the second shielding portion away from the first shielding portion, where an orthographic projection of the second connecting portion on the base substrate extends along the column direction; a third connecting portion, connected to a side of the second shielding portion in a row direction, where an orthographic projection of the third connecting portion on the base substrate extends along the row direction; and a fourth connecting portion, connected to a side, in the row direction, of the second shielding portion away from the third connecting portion, where an orthographic projection of the fourth connecting portion on the base substrate extends along the row direction. In two shielding units adjacent to each other in the row direction, the third connecting portion in one shielding unit is connected to the fourth connecting portion in the other shielding unit. In two shielding units adjacent to each other in the column direction, the first connecting portion in one shielding unit is connected to the second connecting portion in the other shielding unit.

In some embodiments of the present disclosure, the pixel driving circuit further includes a first transistor, and a second electrode of the first transistor is connected to the gate of the driving transistor. The active layer further includes: a first active portion, configured to form a channel region of the first transistor, where the first active portion including a fifth active sub-portion and a sixth active sub-portion. The first connecting portion includes a first constituent part and a second constituent part, the first constituent part is connected between the first shielding portion and the second constituent part, an orthographic projection of the first constituent part on the base substrate extends along the row direction, an orthographic projection of the second constituent part on the base substrate extends along the column direction, and the orthographic projection of the second constituent part on the base substrate is located between orthographic projections of the fifth active sub-portion and the sixth active sub-portion on the base substrate.

In some embodiments of the present disclosure, the second connecting portion includes a third constituent part, a fourth constituent part and a fifth constituent part, the fourth constituent part is connected between the third constituent part and the fifth constituent part, and orthographic projections of both the third constituent part and the fifth constituent part on the base substrate extend along the column direction and are staggered in the row direction. In the two shielding units adjacent to each other in the column direction, the fifth constituent part in one shielding unit of a current row is connected to the second constituent part in the other shielding unit of a next row.

In some embodiments of the present disclosure, the display panel further includes: a second source-drain metal layer, located on a side of the a first conductive layer away from the base substrate. The second source-drain metal layer includes: a first power line, where an orthographic projection of the first power line on the base substrate extends along the column direction, and the first power line is connected to at least one of the first connecting portion, the second connecting portion, the third connecting portion and the fourth connecting portion in the first metal layer through a via in a non-display area of the display panel.

In some embodiments of the present disclosure, the second active portion includes a first active sub-portion and a second active sub-portion. The display panel further includes: a first conductive layer, located on the side of the active layer away from the base substrate. The first conductive layer includes: a gate signal line, including a main extension portion and a secondary extension portion connected to a side of the main extension portion, where an orthographic projection of the main extension portion on the base substrate extends along a row direction and covers an orthographic projection of the first active sub-portion on the base substrate, an orthographic projection of the secondary extension portion on the base substrate extends along a column direction and covers an orthographic projection of the second active sub-portion on the base substrate, and the secondary extension portion and a partial structure of the main extension portion are configured to form a gate of the second transistor. The first metal layer includes a plurality of shielding units, with each of the shielding units corresponding to one pixel driving circuit, the shielding unit includes a first shielding portion arranged corresponding to the second active portion, and an orthographic projection of the first shielding portion on the base substrate overlaps with the orthographic projection of the second active portion on the base substrate. The first shielding portion includes a first shielding sub-portion and a second shielding sub-portion, the first shielding sub-portion corresponds to the first active sub-portion, the second shielding sub-portion corresponds to the second active sub-portion, an orthographic projection of the first shielding sub-portion on the base substrate extends along the row direction and has a fifth width in the column direction, a first overlapping portion is formed between the orthographic projections of the main extension portion and the first shielding sub-portion on the base substrate and has a seventh width in the column direction, and the fifth width is greater than the seventh width; an orthographic projection of the second shielding sub-portion on the base substrate extends along the column direction and has a sixth width in the row direction, a second overlapping portion is formed between the orthographic projections of the secondary extension portion and the second active sub-portion on the base substrate and has an eighth width in the row direction, and the sixth width is greater than the eighth width.

In some embodiments of the present disclosure, a ratio of the seventh width to the fifth width and a ratio of the eighth width to the sixth width are both greater than or equal to 50%.

In some embodiments of the present disclosure, the second overlapping portion has a first length in the column direction; and the orthographic projection of the secondary extension portion on the base substrate has a second length in the column direction, where the first length is smaller than the second length.

In some embodiments of the present disclosure, the display panel further includes: a first electrode layer, located on the side of the active layer away from the base substrate, where the first electrode layer including a plurality of first electrodes, with each of the first electrodes corresponding to one pixel driving circuit. The display panel includes a first sub-pixel, a second sub-pixel and a third sub-pixel, with each sub-pixel corresponding to one pixel driving circuit, where a first electrode of the first sub-pixel and a first electrode of the third sub-pixel are located in a first pixel column, a first electrode of the second sub-pixel is located in a second pixel column, and the first pixel column and the second pixel column are alternately distributed in a row direction.

In some embodiments of the present disclosure, the second metal layer is the first electrode layer; the second active portion includes a first active sub-portion and a second active sub-portion. The active layer further includes: a ninth active portion, connected between the first active sub-portion and the second active sub-portion. An orthographic projection of at least part of the first electrodes on the base substrate covers orthographic projections of the second active portion, the third active portion and the ninth active portion on the base substrate.

In some embodiments of the present disclosure, the display panel includes a plurality of first repeating units arranged in an array along row and column directions, where the first repeating unit includes a first pixel driving circuit and a second pixel driving circuit adjacently arranged in the row direction. In any of the first repeating units, an orthographic projection, on the base substrate, of a first electrode connected to the first pixel driving circuit covers orthographic projections, on the base substrate, of the second active portion and the ninth active portion in the first pixel driving circuit, and partially overlaps with the orthographic projection of the third active portion on the base substrate; the orthographic projection, on the base substrate, of the first electrode connected to the first pixel driving circuit also at least partially overlaps with orthographic projections, on the base substrate, of the second active portion and the ninth active portion in the second pixel driving circuit; an orthographic projection, on the base substrate, of a first electrode connected to the second pixel driving circuit partially overlaps with an orthographic projection, on the base substrate, of the third active portion in the second pixel driving circuit.

In some embodiments of the present disclosure, in any of the first repeating units, the orthographic projection, on the base substrate, of the first electrode connected to the first pixel driving circuit also covers the orthographic projection, on the base substrate, of the third active portion in the first pixel driving circuit and/or also covers the orthographic projections, on the base substrate, of the second active portion and the ninth active portion in the second pixel driving circuit.

In some embodiments of the present disclosure, the first sub-pixel and the third sub-pixel both correspond to the first pixel driving circuit, and the second sub-pixel corresponds to the second pixel driving circuit.

In some embodiments of the present disclosure, the ninth active portion includes a third active sub-portion and a fourth active sub-portion, the third active sub-portion is connected to the first active sub-portion, and the fourth active sub-portion is connected to the second active sub-portion; the first electrodes in the first sub-pixel and the third sub-pixel each include a main portion and an additional portion, and the additional portion is connected to a side of the main portion along the row direction. The display panel further includes: a first conductive layer, located between the active layer and the first electrode layer. The first conductive layer includes: a gate signal line, including a main extension portion and a secondary extension portion, where an orthographic projection of the main extension portion on the base substrate extends along the row direction and covers an orthographic projection of the first active sub-portion on the base substrate, an orthographic projection of the secondary extension portion on the base substrate extends along a column direction and covers an orthographic projection of the second active sub-portion on the base substrate, and the secondary extension portion and a partial structure of the main extension portion are configured to form a gate of the second transistor. The display panel includes a plurality of first repeating units arranged in an array along the row and column directions, the first repeating unit includes a first pixel driving circuit and a second pixel driving circuit adjacently arranged in the row direction, the first pixel driving circuit is located in a first pixel column, and the second pixel driving circuit is located in a second pixel column. In the same first repeating unit, an orthographic projection, on the base substrate, of the main portion of the first electrode in the first sub-pixel covers the orthographic projections, on the base substrate, of the second active portion, the third active portion and the ninth active portion in the first pixel driving circuit, and also covers orthographic projections, on the base substrate, of the first active sub-portion and the third active sub-portion in the second pixel driving circuit; and an orthographic projection, on the base substrate, of the additional portion of the first electrode in the first sub-pixel covers orthographic projections, on the base substrate, of the second active sub-portion and the fourth active sub-portion in the second pixel driving circuit. In the same first repeating unit, an orthographic projection, on the base substrate, of the main portion of the first electrode in the third sub-pixel covers the orthographic projections, on the base substrate, of the second active portion and the ninth active portion in the first pixel driving circuit and at least partially overlaps with the orthographic projection of the third active portion on the base substrate, and an orthographic projection, on the base substrate, of the additional portion of the first electrode in the third sub-pixel covers orthographic projections, on the base substrate, of the second active sub-portion and the ninth active portion in the second pixel driving circuit and at least partially overlaps with the orthographic projection of the first active sub-portion on the base substrate.

In some embodiments of the present disclosure, the second metal layer is a second source-drain metal layer, and the second source-drain metal layer is located between the active layer and the first electrode layer. The second source-drain metal layer includes: an electrode planarization portion, arranged corresponding to the first electrode of a corresponding sub-pixel, where an orthographic projection of the first electrode on the base substrate is located on an orthographic projection of the electrode planarization portion on the base substrate; the orthographic projection of the electrode planarization portion on the base substrate also at least partially overlaps with the orthographic projections, on the base substrate, of the second active portion and the third active portion in the same pixel driving circuit.

In some embodiments of the present disclosure, the display panel includes a plurality of first repeating units arranged in an array along row and column directions, and the first repeating unit includes a first pixel driving circuit and a second pixel driving circuit arranged adjacently in the row direction. The ninth active portion includes a third active sub-portion and a fourth active sub-portion, the third active sub-portion is connected to the first active sub-portion, and the fourth active sub-portion is connected to the second active sub-portion. The display panel further includes: a first conductive layer, located between the active layer and the second source-drain metal layer. The first conductive layer includes: a gate signal line, including a main extension portion and a secondary extension portion, where an orthographic projection of the main extension portion on the base substrate extends along the row direction and covers an orthographic projection of the first active sub-portion on the base substrate, and an orthographic projection of the secondary extension portion on the base substrate extends along a column direction and covers an orthographic projection of the second active sub-portion on the base substrate. The electrode planarization portion includes a second planarization part located in the second pixel column, and the second planarization part includes a first extension, a second extension and a third extension sequentially connected in the column direction. In the same first repeating unit, an orthographic projection of the first extension on the base substrate covers orthographic projections, on the base substrate, of the second active sub-portion and the fourth active sub-portion in the same pixel driving circuit and partially overlaps with orthographic projections of the first active sub-portion and the third active sub-portion on the base substrate, an orthographic projection of the second extension on the base substrate partially overlaps with the orthographic projection, on the base substrate, of the third active portion in the same pixel driving circuit, and an orthographic projection of the third extension on the base substrate is located within an orthographic projection, on the base substrate, of the first electrode in a corresponding sub-pixel.

In some embodiments of the present disclosure, a hollow portion is provided between the first extension and the second extension, and the hollow portion is configured to expose at least a partial gap between the second transistor and the driving transistor.

In some embodiments of the present disclosure, the orthographic projection of the first extension on the base substrate has a first width in the row direction, the orthographic projection of the second extension on the base substrate has a second width in the row direction, and the orthographic projection of the third extension on the base substrate has a third width in the row direction, where the second width is smaller than the first width and smaller than the third width.

In some embodiments of the present disclosure, the display panel includes a plurality of first repeating units arranged in an array along row and column directions, the first repeating unit includes a first pixel driving circuit and a second pixel driving circuit arranged adjacently in the row direction. The electrode planarization portion includes: a first planarization part, located in the first pixel column and arranged corresponding to the first sub-pixel, where an orthographic projection of the first planarization part on the base substrate covers orthographic projections, on the base substrate, of the second active sub-portion, the fourth active sub-portion and the third active portion in the same pixel driving circuit, and an orthographic projection, on the base substrate, of the first electrode in the first sub-pixel covers the orthographic projection of the first planarization part on the base substrate; a second planarization part, located in the second pixel column, where an orthographic projection of the second planarization part on the base substrate partially overlaps with the second active portion, the third active portion and the ninth active portion in the same pixel driving circuit; and a third planarization part, located in the first pixel column and arranged corresponding to the third sub-pixel, where an orthographic projection of the third planarization part on the base substrate covers orthographic projections, on the base substrate, of the second active sub-portion and the fourth active sub-portion in the same pixel driving circuit and at least partially overlaps with the orthographic projection of the third active portion on the base substrate, and an orthographic projection, on the base substrate, of the first electrode in the third sub-pixel covers the orthographic projection of the third planarization part on the base substrate.

In some embodiments of the present disclosure, the orthographic projection of the first electrode in the first sub-pixel on the base substrate has a first area, the orthographic projection of the first electrode in the second sub-pixel on the base substrate has a second area, and the orthographic projection of the first electrode in the third sub-pixel on the base substrate has a third area, where the first area>the third area>the second area. The first planarization part has a first extension length in the column direction, the second planarization part has a second extension length in the column direction, and the third planarization part has a third extension length in the column direction, where the second extension length>the first extension length>the third extension length.

In some embodiments of the present disclosure, in any of the first repeating units, the orthographic projections, on the base substrate, of both the first electrode in the first sub-pixel and the first electrode in the third sub-pixel cover the orthographic projections, on the base substrate, of the second active portion, the ninth active portion and the third active portion in a corresponding first pixel driving circuit; the orthographic projection, on the base substrate, of the first electrode in the first sub-pixel also covers the orthographic projections, on the base substrate, of the second active portion and the ninth active portion in a corresponding second pixel driving circuit; and the orthographic projection, on the base substrate, of the first electrode in the third sub-pixel at least partially overlaps with the orthographic projections, on the base substrate, of the second active portion and the ninth active portion in the corresponding second pixel driving circuit.

In some embodiments of the present disclosure, the display panel includes a plurality of second repeating units arranged in an array along row and column directions, and the second repeating unit includes a third pixel driving circuit and a fourth pixel driving circuit arranged adjacently in the row direction. The display panel further includes a first conductive layer and a second conductive layer stacked on the side of the active layer away from the base substrate. In the same second repeating unit, structures of a first metal layer, an active layer, a first conductive layer and a second conductive layer in the third pixel driving circuit and structures of a first metal layer, an active layer, a first conductive layer and a second conductive layer in the fourth pixel driving circuit are arranged as mirror images of each other. In any two adjacent second repeating units in the row direction, structures of a first metal layer, an active layer, a first conductive layer and a second conductive layer in one second repeating unit and structures of a first metal layer, an active layer, a first conductive layer and a second conductive layer in another second repeating unit are arranged as mirror images of each other.

In some embodiments of the present disclosure, the second metal layer is a second source-drain metal layer; and the second source-drain metal layer includes: a plurality of electrode planarization portions, arranged in an array along the row and column directions, with each of the electrode planarization portions being provided corresponding to one second repeating unit. In the same repeating unit, an orthographic projection of the electrode planarization portion on the base substrate at least partially overlaps with orthographic projections of two second active portions, two ninth active portions and two third active portions on the base substrate.

In some embodiments of the present disclosure, the second metal layer is the first electrode layer; each first electrode located in a first sub-pixel row is correspondingly located in one of the second repeating units. In any of the second repeating units, an orthographic projection, on the base substrate, of the first electrode located in the first sub-pixel row covers orthographic projections of two second active portions and two ninth active portions on the base substrate, and at least partially overlaps with orthographic projections of two third active portions on the base substrate.

In some embodiments of the present disclosure, in any two adjacent second repeating units in the row direction, a data signal line and a first power line of a third pixel driving circuit in one repeating unit are mirror-symmetrical with a data signal line and a first power line of a fourth pixel driving circuit in the other repeating unit, the data signal line in one third pixel driving circuit is arranged adjacent to the data signal line in the other repeating unit being mirror-symmetrical thereto, the first power line in one third pixel driving circuit and the first power line in the other repeating unit being mirror-symmetrical thereto are respectively located on both sides of the two data signal lines. An orthographic projection, on the base substrate, of the first electrode in a second sub-pixel row is located on orthographic projections, on the base substrate, of the first power line and the data signal line of two adjacent second repeating units in the row direction.

In some embodiments of the present disclosure, the pixel driving circuit further includes a first transistor, the driving transistor, a fourth transistor and a seventh transistor; a first electrode of the first transistor is connected to a first initialization signal terminal, and a second electrode of the first transistor is connected to the gate of the driving transistor; a first electrode of the fourth transistor is connected to a second electrode of the driving transistor, and a second electrode of the fourth transistor is connected to a data signal terminal; a first electrode of the seventh transistor is connected to a second initialization signal terminal, and a second electrode of the seventh transistor is connected to a first electrode of a light-emitting device. The active layer further includes: an eleventh active portion, configured to form the second electrode of the first transistor; a twelfth active portion, configured to form the first electrode of the first transistor; a fourteenth active portion, configured to form the second electrode of the fourth transistor; a fifteenth active portion, configured to form the first electrode of the seventh transistor; a seventeenth active portion, configured to form a first electrode of a fifth transistor. The display panel further includes: a first conductive layer, located between the active layer and the first electrode layer, where the first conductive layer includes: a first conductive block, where an orthographic projection of the first conductive block on the base substrate covers the orthographic projection of the third active portion on the base substrate, and the first conductive block is configured to form the gate of the driving transistor. The display panel further includes: a second conductive layer, located between the first conductive layer and the first electrode layer, where the second conductive layer includes: a first initialization signal line, where an orthographic projection of the first initialization signal line on the base substrate extends along the row direction; and a second initialization signal line, where an orthographic projection of the second initialization signal line on the base substrate extends along the row direction. The display panel further includes: a first source-drain metal layer, located between the second conductive layer and the first electrode layer, where the first source-drain metal layer includes: a first bridge portion, where an orthographic projection of the first bridge portion on the base substrate extends along the column direction, one end of the first bridge portion is connected to the eleventh active portion through a via, and the other end of the first bridge portion is connected to the first conductive block through a via, thereby connecting the second electrode of the first transistor to the gate of the driving transistor; a second bridge portion, where an orthographic projection of the second bridge portion on the base substrate extends along the column direction, one end of the second bridge portion is connected to the fifteenth active portion through a via, and the other end of the second bridge portion is connected to the second initialization signal line through a via, thereby connecting the first electrode of the seventh transistor to the second initialization signal line; a third bridge portion, where an orthographic projection of the third bridge portion on the base substrate extends along the column direction, one end of the third bridge portion is connected to the twelfth active portion through a via, and the other end of the third bridge portion is connected to the first initialization signal line through a via, thereby connecting the first electrode of the first transistor to the first initialization signal line; a power adapter line, where an orthographic projection of the power adapter line extends in the column direction, and the power adapter line is connected to the seventeenth active portion through a via, thereby being connected to the first electrode of the fifth transistor; and a data adapter portion, connected to the fourteenth active portion through a via, thereby being connected to the second electrode of the fourth transistor. The display panel further includes: a second source-drain metal layer, located between the first source-drain metal layer and the first electrode layer, and the second source-drain metal layer includes: a data signal line, where an orthographic projection of the data signal line on the base substrate extends along the column direction, and the data signal line is connected to the data adapter portion through a via; and a first power line, where an orthographic projection of the first power line on the base substrate extends along the column direction, and the first power line is connected to the power adapter line through a via. Two first bridge portions, two second bridge portions, two third bridge portions, two power adapter lines, two data adapter portions, two data signal lines and two first power lines in any of the second repeating units are mirror-symmetrical respectively.

In some embodiments of the present disclosure, the pixel driving circuit includes a seventh transistor, and a first electrode of the seventh transistor is connected to a second initialization signal terminal; the display panel includes a first display area and a second display area at least partially surrounding the first display area, the first display area has a greater light transmittance than the second display area, and the first display area includes a plurality of pixel rows. The active layer further includes: a fifteenth active portion, configured to form the first electrode of the seventh transistor. The display panel further includes: a second conductive layer, located between the active layer and the second metal layer, where the second conductive layer includes: a second initialization signal line, where an orthographic projection of the second initialization signal line on the base substrate extends along a row direction. The display panel further includes: a first source-drain metal layer, located between the second conductive layer and the second metal layer, where the first source-drain metal layer includes: a second bridge portion, where an orthographic projection of the second bridge portion on the base substrate extends along a column direction, one end of the second bridge portion is connected to the fifteenth active portion through a via, and the other end of the second bridge portion is connected to the second initialization signal line through a via, thereby connecting the first electrode of the seventh transistor to the second initialization signal line; and a first connecting line, located in the second display area, where an orthographic projection of the first connecting line on the base substrate extends along the column direction, and the first connecting line is connected to two second bridge portions of two adjacent rows.

According to a second aspect of the present disclosure, a display device is also provided and includes the display panel described in any embodiment of the present disclosure.

In the display panel provided by the present disclosure, the first metal layer only blocks the second active portion and the third active portion from below the active layer, thereby reducing the shielding area of the first metal layer for the active layer, reducing the amount of light reflected from the first metal layer to the active layer, and further reducing photo-induced leakage and mitigating the color deviation problem caused by strong light exposure. The second metal layer blocks the second active portion and the third active portion above the active layer, thereby reducing the amount of incident light, and correspondingly reducing the amount of light reflected from the first metal layer to the active layer, and further reducing photo-induced leakage and also mitigating the color deviation problem caused by strong light exposure. Based on the present disclosure, the effect of mitigating the color deviation caused by strong light exposure can be fully improved by having the first metal layer and the second metal layer act simultaneously on the upper and lower sides of the active layer.

It is to be understood that the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. The accompanying drawings described below are only some embodiments of the present disclosure, and for those skilled in the art, other accompanying drawings can be obtained based on these accompanying drawings without creative work.

FIG. 1 is a schematic diagram of a circuit structure of a pixel driving circuit in a display panel according to an embodiment of the present disclosure.

FIG. 2 is a timing diagram of each node in a driving method of the pixel driving circuit in FIG. 1.

FIG. 3 is a schematic diagram showing the principle of color deviation caused by a bottom metal layer in the related art.

FIG. 4 is a structural diagram of a display panel according to an embodiment of the present disclosure.

FIG. 5 is a structural diagram of the first metal layer in FIG. 4.

FIG. 6 is a structural layout of the active layer in FIG. 4.

FIG. 7 is a structural layout of the first conductive layer in FIG. 4.

FIG. 8 is a stacked layout of the first metal layer, the active portion and the first conductive layer in FIG. 4.

FIG. 9 is a partial enlarged view of the second transistor in FIG. 8.

FIG. 10 is a schematic connection diagram of the first metal layer in row and column directions in FIG. 4.

FIG. 11 is a partial enlarged view of a stack of a first metal layer, an active layer and a first conductive layer in the related art.

FIG. 12 is a structural layout of the second conductive layer in FIG. 4.

FIG. 13 is a structural layout of the first source-drain metal layer in FIG. 4.

FIG. 14 is a structural layout of the second source-drain metal layer in FIG. 4.

FIG. 15 is a structural layout of the first electrode layer in FIG. 4.

FIG. 16 is a stacked layout of the first source-drain metal layer, the second source-drain metal layer and the first electrode layer in FIG. 4.

FIG. 17 is a schematic structural diagram of a display panel according to an embodiment of the present disclosure.

FIG. 18 is a schematic diagram of an arrangement of sub-pixels according to an embodiment of the present disclosure.

FIG. 19 is a schematic diagram of an arrangement of sub-pixels according to another embodiment of the present disclosure.

FIG. 20 is a structural layout of a display panel according to another embodiment of the present disclosure.

FIG. 21 is a structural layout of the first electrode layer in FIG. 20.

FIG. 22 is a stacked layout of the active layer, the first conductive layer and the first electrode layer in FIG. 20.

FIG. 23 is a partial enlarged view corresponding to the first electrode of the first pixel driving circuit extending to the second transistor of the second pixel driving circuit in FIG. 22.

FIG. 24 is a structural layout of a first metal layer according to an embodiment of the present disclosure.

FIG. 25 is a structural layout of a display panel according to another embodiment of the present disclosure.

FIG. 26 is a structural layout of the second source-drain metal layer in FIG. 25.

FIG. 27 is a stacked layout of the active layer and the second source-drain metal layer in FIG. 25.

FIG. 28 is a stacked layout of the active layer, the second source-drain metal layer and the first electrode layer in FIG. 25.

FIG. 29 is a structural layout of a display panel according to another embodiment of the present disclosure.

FIG. 30 is a structural layout of the first metal layer in FIG. 29.

FIG. 31 is a structural layout of the active layer in FIG. 29.

FIG. 32 is a structural layout of the first conductive layer in FIG. 29.

FIG. 33 is a structural layout of the second conductive layer in FIG. 29.

FIG. 34 is a structural layout of the first source-drain metal layer in FIG. 29.

FIG. 35 is a structural layout of the second source-drain metal layer in FIG. 29.

FIG. 36 is a structural layout of the first electrode layer in FIG. 29.

FIG. 37 is a stacked layout of the active layer and the second source-drain metal layer in FIG. 29.

FIG. 38 is a stacked layout of the active layer, the second source-drain metal layer and the first electrode layer in FIG. 29.

FIG. 39 is a cross-sectional view along the AA direction in FIG. 4.

### DETAILED DESCRIPTION

Exemplary embodiments will now be described more fully with reference to the accompanying drawings. However, exemplary embodiments can be implemented in a variety of forms and should not be construed as limited to the embodiments set forth herein. Rather, these embodiments are provided so that the present disclosure will be comprehensive and complete and fully convey the concepts of the exemplary embodiments to those skilled in the art. The same reference numerals in the drawings represent the same or similar structures, and thus their detailed description will be omitted. In addition, the drawings are only schematic illustrations of the present disclosure and are not necessarily drawn to scale.

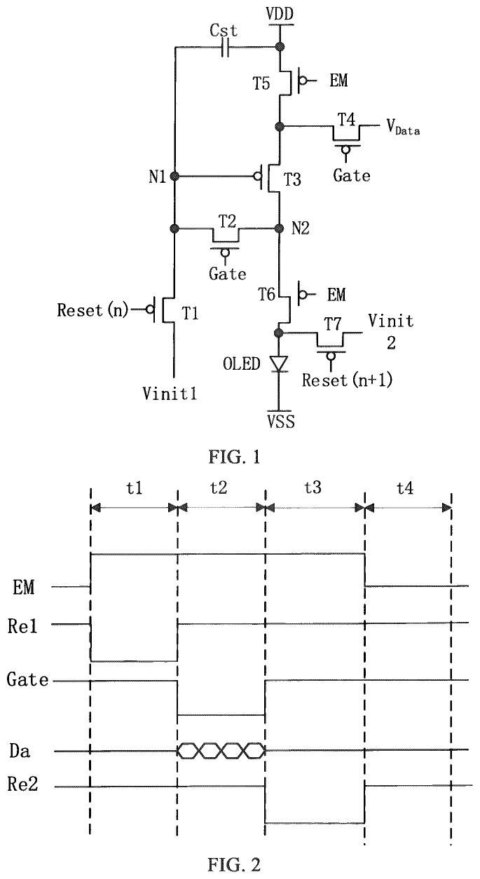

FIG. 1 is a schematic diagram of a circuit structure of a pixel driving circuit in a display panel according to an embodiment of the present disclosure. The pixel driving circuit may include: a first transistor T1, a second transistor T2, a driving transistor T3, a fourth transistor T4, a fifth transistor T5, a sixth transistor T6, a seventh transistor T7, and a storage capacitor C. Here, the first electrode of the first transistor T1 is connected to the first initial signal terminal Vinit1, the second electrode thereof is connected to the first node N1, and the gate thereof is connected to the first reset signal terminal Reset n. The first electrode of the second transistor T2 is connected to the gate of the driving transistor T3, the second electrode thereof is connected to the first electrode of the driving transistor, and the gate thereof is connected to the gate signal terminal Gate. The gate of the driving transistor T3 is connected to the first node N1. The second electrode of the fourth transistor T4 is connected to the data signal terminal V Data, the first electrode thereof is connected to the second electrode of the driving transistor T3, and the gate thereof is connected to the gate signal terminal Gate. The second electrode of the fifth transistor T5 is connected to the second electrode of the driving transistor T3, the first electrode thereof is connected to the first power supply terminal VDD, and the gate thereof is connected to the enable signal terminal EM. The first electrode of the sixth transistor T6 is connected to the first electrode of the driving transistor T3, and the gate thereof is connected to the enable signal terminal EM. The first electrode of the seventh transistor T7 is connected to the second initial signal terminal Vinit2, the second electrode thereof is connected to the second electrode of the sixth transistor T6, and the gate thereof is connected to the second reset signal terminal Reset (n+1). The first electrode of the storage capacitor C is connected to the first node N1, and the second electrode thereof is connected to the first power supply terminal VDD. The pixel driving circuit can be connected to a light-emitting unit OLED to drive the light-emitting unit OLED to emit light, and the light-emitting unit OLED can be connected between the second electrode of the sixth transistor T6 and the second power supply terminal VSS. Here, each transistor in the present disclosure can be a P-type transistor. For example, the first transistor T1 to the seventh transistor T7 can each be a P-type low-temperature polycrystalline silicon transistor, which has a high carrier mobility, thereby realizing a display panel with high resolution, high response speed, high pixel density, and high aperture ratio. The first initial signal terminal Vinit1 and the second initial signal terminal Vinit2 can output the same or different voltage signals according to actual conditions.

It should be noted that the transistors used in each embodiment of the present disclosure can be thin film transistors or field effect transistors or other devices with the similar characteristics. In this specification, the first electrode can be a drain electrode and the second electrode can be a source electrode; or the first electrode can be a source electrode and the second electrode can be a drain electrode.

FIG. 2 is a timing diagram of each node in a driving method of the pixel driving circuit in FIG. 1. As shown in FIG. 2, in the drawings, G1 represents the timing of the gate signal terminal Gate, Re1 represents the timing of the first reset signal terminal Reset n, Re2 represents the timing of the second reset signal terminal Reset (n+1), EM represents the timing of the enable signal terminal EM, and Da represents the timing of the data signal terminal V_{Data}. The driving method of the pixel driving circuit may include a first reset stage t1, a compensation stage t2, a second reset stage t3, and a light-emitting stage t4. In the first reset stage t1: the first reset signal terminal Reset n outputs a low-level signal, the first transistor T1 is turned on, and the first initial signal terminal Vinit1 inputs an initial signal to the first node N1. In the compensation stage t2: the gate signal terminal Gate outputs a low-level signal, the second transistor T2 and the fourth transistor T4 are turned on, and at the same time the data signal terminal V_{Data} Outputs a data signal to write a voltage Vdata+Vth (i.e., the sum of the voltage Vdata and Vth) to the first node N1, where Vdata is the voltage of the driving signal, and Vth is the threshold voltage of the driving transistor T3. In the second reset stage t3, the second reset signal terminal Reset (n+1) outputs a low-level signal, the seventh transistor T7 is turned on, and the second initial signal terminal Vinit2 inputs an initial signal to the second electrode of the sixth transistor T6. In the light-emitting stage t4: the enable signal terminal EM outputs a low-level signal, the sixth transistor T6 and the fifth transistor T5 are turned on, and the driving transistor T3 emits light under the action of the voltage Vdata+Vth stored in the storage capacitor C.

According to the output current formula of the driving transistor: I=(μWCox/2L)(Vgs−Vth)2, where u is the carrier mobility; Cox is the gate storage capacitance per unit area, W is the channel width of the driving transistor, L is the channel length of the driving transistor, Vgs is the gate-source voltage difference of the driving transistor, and Vth is the threshold voltage of the driving transistor. The output current of the driving transistor in the pixel driving circuit of the present disclosure is I=(μWCox/2L)(Vdata+Vth−Vdd−Vth)². The pixel driving circuit can avoid the influence of the threshold of the driving transistor on its output current.

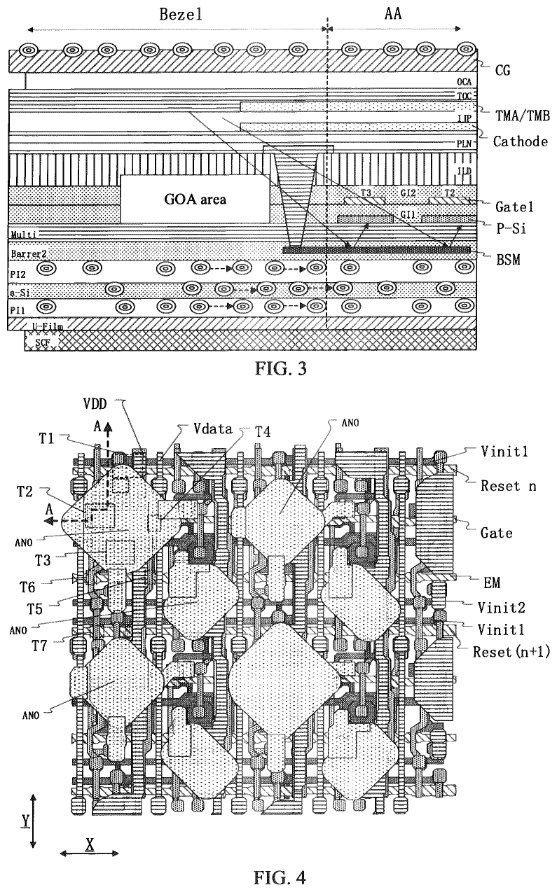

In the related art, the luminous efficiency of light-emitting devices is getting higher and higher to meet the needs of longer life and lower power consumption of display devices. However, the excessively high luminous efficiency makes it more sensitive to changes in the characteristics of TFT, which will affect the TFT characteristics in the panel after the reliability test. Because the luminous efficiency of each device is different, the panel after the reliability test will have a color shift problem. For this reason, a metal layer is usually provided at the bottom of the semiconductor layer to solve the problem of color shift in the reliability test. However, as shown in FIG. 3, after the metal layer is provided at the bottom, strong light will be reflected to the active layer Polly through the bottom metal layer, generating photogenerated carriers and causing leakage of the pixel driving circuit, which will reduce the display brightness of each RGB sub-pixel; and the second sub-pixel G will attenuate more, causing the local area of the display panel to appear reddish and pink. The display panel according to the present disclosure is proposed to solve the above-mentioned color shift problem caused by strong light irradiation.

The display panel provided by the present disclosure may include multiple pixel driving circuits distributed in an array along the row direction X and the column direction Y, where the pixel driving circuit is used to drive the light-emitting device to emit light. The pixel driving circuit can be as shown in FIG. 1. Alternatively, in other exemplary embodiments, the pixel driving circuit in the display panel can also be other structures, such as 8T1C, 9T1C, and the like. FIG. 4 is a structural layout of a display panel according to an embodiment of the present disclosure. As shown in FIG. 4, the display panel of the present disclosure may include a substrate, an active layer Polly, a first metal layer BSM and a second metal layer. The active layer Polly is located on a side of the base substrate. The active layer Polly may include a second active portion POL2 and a third active portion POL3. The second active portion POL2 may be used to form a channel region of the second transistor T2. The third active portion POL3 is connected to the second active portion POL2. The third active portion POL3 may be used to form a channel region of the driving transistor T3. The first metal layer BSM is located between the base substrate and the active layer Polly. The second metal layer is located on a side of the active layer Polly away from the base substrate. The orthographic projection of the first metal layer BSM on the base substrate covers the orthographic projections of the second active portion POL2 and the third active portion POL3 on the base substrate, and the orthographic projection of the second metal layer on the base substrate at least covers the orthographic projection of the second active portion POL2 on the base substrate.

In the display panel provided by the present disclosure, the first metal layer BSM only blocks the second active portion POL2 and the third active portion POL3 from below the active layer Polly, reducing the shielding area of the first metal layer BSM for the active layer Polly, thereby reducing the amount of light reflected to the active layer Polly through the first metal layer BSM, reducing photo-induced leakage, and mitigating the color deviation problem caused by strong light exposure. The second metal layer blocks the second active portion POL2 and the third active portion POL3 above the active layer Polly, thereby reducing the amount of incident light, and correspondingly reducing the amount of light reflected to the active layer Polly through the first metal layer BSM, thereby reducing photo-induced leakage, and thus further mitigating the color deviation problem caused by strong light exposure. Based on the present disclosure, the effect of mitigating the color deviation caused by strong light exposure can be fully improved by having the first metal layer BSM and the second metal layer act simultaneously on the upper and lower sides of the active layer Polly.

The base substrate of the present disclosure may be a flexible substrate, for example, a flexible substrate of PI material. There are a large number of free charges in the flexible substrate. After the temperature rises, the free charges will diffuse to the channel region of the transistor and cause the threshold voltage of the transistor to drift positively. Taking the pixel driving circuit shown in FIG. 1 as an example, after the threshold voltage of the second transistor T2 and the driving transistor T3 drifts positively, the voltage of the first node N1 will be reduced, so that the gate-source voltage of the driving transistor T3 will decrease accordingly, and the driving current provided by the pixel driving circuit increases, thereby causing the screen to be brighter than before the reliability test and the copper rod test. Moreover, because the luminous efficiency of the second sub-pixel G is the highest, so the problem of bright display after friction test is usually manifested as green display after test, which is more easily perceived by human eyes when low gray scale is displayed, that is, the problem is more obvious under low gray scale. Based on the present disclosure, the first metal layer BSM is provided below the active layer Polly, and the free charge at the bottom can be blocked by the first metal layer BSM, thereby solving the color deviation problem after high temperature reliability test. On this basis, because the orthographic projection of the first metal layer BSM on the base substrate only covers the orthographic projections of the second active portion POL2 and the third active portion POL3 on the base substrate, that is, the first metal layer BSM only blocks the channel of the second transistor T2 and the driving transistor T3 in the pixel driving circuit, reducing the blocking area of the first metal layer BSM for the active layer Polly, so that the light incident from the display side to the first metal layer BSM at the bottom can be reduced, the amount of light reflected by the first metal layer BSM to the active layer Polly can be reduced, thereby reducing the photogenerated carriers, and further solving the display color deviation problem caused by the generation of photogenerated carriers due to strong light irradiation.

The orthographic projection of the first metal layer on the base substrate at least partially overlaps with the orthographic projections of both the second active portion and the third active portion on the base substrate, that is, overlapping portions exist between the orthographic projection of the first metal layer on the base substrate and the orthographic projections of the second active portion and the third active portion on the base substrate. In some embodiments, the orthographic projection of the first metal layer on the base substrate can completely cover the orthographic projections of the second active portion and the third active portion on the base substrate. In the present disclosure, when referring to that the orthographic projection of a certain structure A on the base substrate covers the orthographic projection of another structure B on the base substrate, it can be understood as that the projected contour of the structure B on the base substrate plane is completely located inside the projected contour of the structure A in the same plane. For example, when referring to that the orthographic projection of the first metal layer BSM on the base substrate covers the orthographic projection of the second active portion POL2 on the base substrate, it means that the contour of the orthographic projection of the second active portion POL2 on the base substrate is completely located within the contour of the orthographic projection of the first metal layer BSM on the base substrate. In this way, it is equivalent to that the first metal layer BSM completely blocks the channel region of the second transistor T2 and the channel region of the driving transistor T3 at the bottom of the active layer Polly. In other words, when referring to that the orthographic projection of the first metal layer BSM on the base substrate covers the orthographic projection of the second active portion POL2 on the base substrate, it is equivalent to having a first metal layer structure opposite to and larger in area than the second active portion POL2 below the second active portion POL2, that is, the boundary of the first metal layer structure exceeds the boundary of the second active portion POL2.

In some other embodiments, the orthographic projection of the first metal layer on the base substrate may also partially overlap with the orthographic projections of the second active portion and the third active portion on the base substrate, that is, a part of the orthographic projection of the second active portion on the base substrate is located within the contour of the orthographic projection of the first metal layer on the base substrate, and another part thereof is located outside the contour of the orthographic projection of the first metal layer on the base substrate; and a part of the orthographic projection of the third active portion on the base substrate is located within the contour of the orthographic projection of the first metal layer on the base substrate, and another part thereof is located outside the contour of the orthographic projection of the first metal layer on the base substrate. In this exemplary embodiment, the ratio of the overlapping area between orthographic projections of the second active portion and the first metal layer on the base substrate to the area of the orthographic projection of the second active portion on the base substrate can be greater than or equal to 50%, for example, it can be 50%, 60%, 70%, 80%, 90%, or the like, so as to enhance the shielding effect of the first metal layer on the second active portion. Similarly, the ratio of the overlapping area between orthographic projections of the third active portion and the first metal layer on the base substrate to the area of the orthographic projection of the third active portion on the base substrate can be greater than or equal to 50%, for example, it can be 50%, 60%, 70%, 80%, 90%, or the like.

Similarly, when referring to that the orthographic projection of the second metal layer on the base substrate at least partially overlaps with the orthographic projections of the second active portion and the third active portion on the base substrate, the orthographic projection of the second metal layer on the base substrate may cover the orthographic projections of the second active portion and the third active portion on the base substrate; or the orthographic projections of both the second active portion and the third active portion on the base substrate may partially overlap with the orthographic projection of the second metal layer on the base substrate.

It can be known that the second metal layer is located above the active layer Polly, that is, on the display side, so that the second metal layer blocks the second active portion POL2 above the active layer Polly, that is, on the display side. In this way, the light incident obliquely from the display side needs a larger angle to be incident on the first metal layer BSM at the bottom. In other words, the amount of light that can be incident on the first metal layer BSM is reduced, and the light reflected from the first metal layer BSM to the active layer Polly is correspondingly reduced, thereby reducing the photogenerated carriers and significantly mitigating the color deviation problem caused by strong light exposure.

The second metal layer of the present disclosure may be the second source-drain metal layer SD2 or the first electrode layer ANOL, and one or more metal layers are used to shield the second transistor T2 and the driving transistor T3, thereby mitigating the color deviation. The present disclosure is further described below in conjunction with the accompanying drawings.

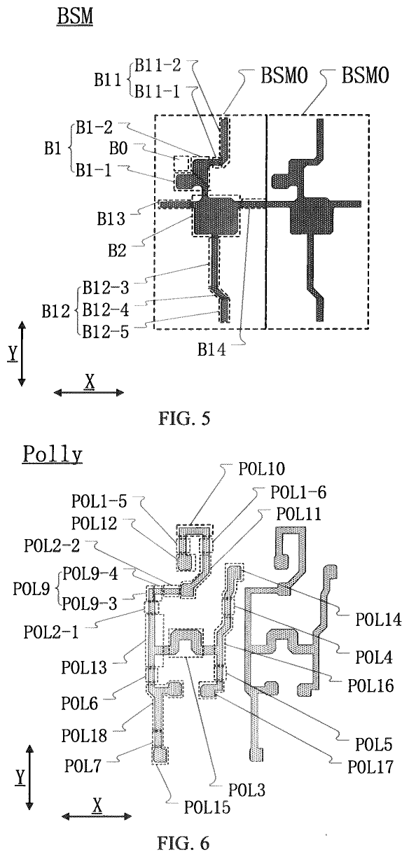

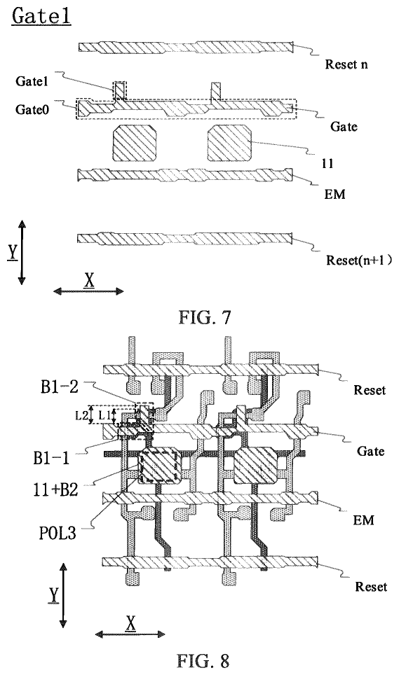

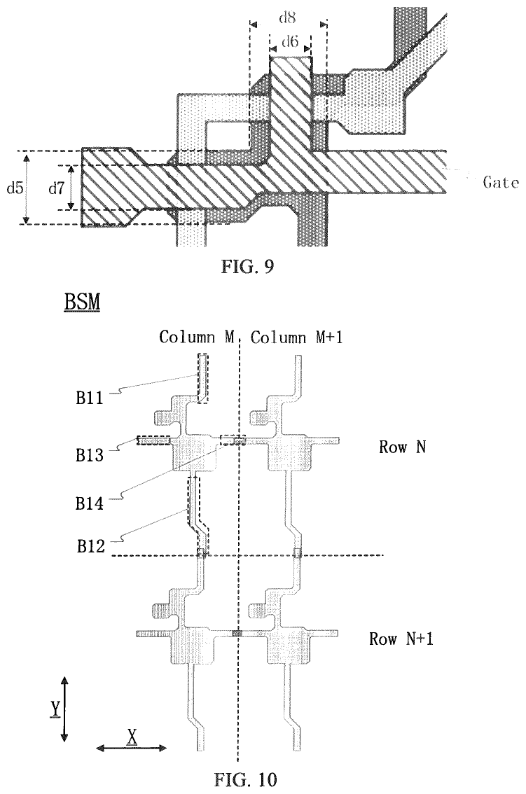

FIG. 5 is a structural layout of the first metal layer in FIG. 4, FIG. 6 is a structural layout of the active layer in FIG. 4, FIG. 7 is a structural layout of the first conductive layer in FIG. 4, FIG. 8 is a stacked layout of the first metal layer, the active portion and the first conductive layer in FIG. 4, FIG. 9 is a local enlarged view of the second transistor in FIG. 8, and FIG. 10 is a schematic connection diagram of the first metal layer in FIG. 4 in the row and column directions.

As shown in FIG. 4 and FIG. 6, the active layer Polly may include a first active portion POL1 to a fifteenth active portion POL15, where the first active portion POL1 can be used to form the channel region of the first transistor T1, the second active portion POL2 can be used to form the channel region of the second transistor T2, the third active portion POL3 can be used to form the channel region of the driving transistor T3, and the fourth active portion POL4 to the seventh active portion POL7 are respectively used to form the channel regions of the fourth transistor T4 to the seventh transistor T7. The active layer Polly of the present disclosure can be formed of polycrystalline silicon semiconductor material, and accordingly, the transistors in the display panel of the present disclosure can be P-type low-temperature polycrystalline silicon thin film transistors.

As shown in FIG. 6, in some exemplary embodiments, the first transistor T1 and the second transistor T2 may be formed in a dual-gate structure. Therefore, the second active portion POL2 may include a first active sub-portion POL2-1 and a second active sub-portion POL2-2, the first active sub-portion POL2-1 and the second active sub-portion POL2-2 are respectively used to form dual channels of the second transistor T2. The first active sub-portion POL2-1 and the second active sub-portion POL2-2 are connected through the ninth active portion POL9, and the ninth active portion POL9 forms a conductor structure T2M of the second transistor T2 after being conductorized. Further, the ninth active portion POL9 may include a third active sub-portion POL9-3 and a fourth active sub-portion POL9-4, where the third active sub-portion POL9-3 is connected to the first active sub-portion POL2-1, and the fourth active sub-portion POL9-4 is connected to the second active sub-portion POL2-2.

The first active portion POL1 may include fifth and sixth active sub-portions POL1-5 and POL 1-6 respectively used for forming dual channels of the first transistor T1, and the fifth and sixth active sub-portions POL1-5 and POL1-6 may be connected through a tenth active portion POL10.

The eleventh active portion POL11 is connected between the second active sub-portion POL2-2 and the sixth active sub-portion POL1-6, and can be used to form the second electrode of the first transistor T1 and the first electrode of the second transistor T2. The eleventh active portion POL 11 can be connected to the first bridge portion 31 of the first source-drain metal layer SD1 through a via, so as to connect the second electrode of the first transistor T1 and the first electrode of the second transistor T2 to the gate of the driving transistor T3 through the first bridge portion 31.

The twelfth active portion POL 12 is connected to a side of the fifth active sub-portion POL1-5. The twelfth active portion POL12 can be used to form the first electrode of the first transistor T1. The twelfth active portion POL12 can be connected to the third bridge portion 33 of the first source-drain metal layer SD1 through a via, so as to connect the first electrode of the first transistor T1 to the first initialization signal line Vinit1 through the third bridge portion 33.

The thirteenth active portion POL13 is connected between the first active sub-portion POL2-1, the third active portion POL3, and the sixth active portion POL6, and the thirteenth active portion POL13 may be used to form the second electrode of the second transistor T2, the first electrode of the sixth transistor T6 and the first electrode of the driving transistor T3.

The fourteenth active portion POL 14 is connected to a side of the fourth active portion POL4 away from the sixteenth active portion POL16. The fourteenth active portion POL14 is used to form the second electrode of the fourth transistor T4. The fourteenth active portion POL 14 can be connected to the data adapter portion VdataL of the first source-drain metal layer SD1 through a via, so as to connect the second electrode of the fourth transistor T4 to the data signal line Vdata through the data adapter portion VdataL.

The sixteenth active portion POL16 is connected between the fourth active portion POL4, the fifth active portion POL5, and the third active portion POL3, and may be used to form the second electrode of the driving transistor T3, the first electrode of the fourth transistor T4, and the second electrode of the fifth transistor T5.

The seventeenth active portion POL17 is connected to a side of the fifth active portion POL5 away from the sixteenth active portion POL16, and the seventeenth active portion POL 17 can be used to form the first electrode of the fifth transistor T5. The seventeenth active portion POL 17 can be connected to the power adapter line VDDL of the first source-drain metal layer SD1 through a via, so as to connect the first electrode of the fifth transistor T5 to the first power line VDD through the power adapter line.

The eighteenth active portion POL18 is connected between the sixth active portion POL6 and the seventh active portion POL7, and the eighteenth active portion POL18 can be used to form the second electrode of the sixth transistor T6 and the second electrode of the seventh transistor T7. The eighteenth active portion POL 18 can be connected to the first adapter portion 301 of the first source-drain metal layer SD1 through a via, so as to connect the second electrode of the sixth transistor T6 and the second electrode of the seventh transistor T7 to the anode of the light-emitting device through the first adapter portion 301.

The fifteenth active portion POL15 is connected to the other side of the seventh active portion POL7. The fifteenth active portion POL 15 can be used to form the first electrode of the seventh transistor T7. The fifteenth active portion POL 15 can be connected to the second bridge portion 32 of the first source-drain metal layer SD1 through a via, so as to connect the first electrode of the seventh transistor T7 to the second initialization signal line Vinit2 through the second bridge portion 32.

As shown in FIG. 4 and FIG. 5, in an exemplary embodiment, the first metal layer BSM may include a plurality of shielding units BSM0, and the plurality of shielding units BSM0 may be arranged one by one corresponding to the plurality of pixel driving circuits. The shielding unit BSM0 may include a first shielding portion B1 and a second shielding portion B2. The first shielding portion B1 is arranged corresponding to the second active portion POL2, and has a notch B0. The orthographic projection of the first shielding portion B1 on the base substrate covers the orthographic projection of the second active portion POL2 on the base substrate. The orthographic projection of the ninth active portion POL9 on the base substrate is located within the orthographic projection of the notch B0 on the base substrate. Thus, the first shielding portion B1 avoids the conductive structure T2M between the double channels of the second transistor T2 through the notch B0. In other words, at the position corresponding to the second transistor T2, the shielding unit BSM0 only blocks the channel region of the second transistor T2 without blocking the conductive structure T2M connecting between the double channels of the second transistor T2. Compared with the solution in the prior art that the first metal layer BSM blocks both the channel and the conductive structure T2M of the second transistor T2 at the second transistor T2, the solution of this exemplary embodiment further reduces the area of the first metal layer BSM, thereby mitigating or eliminating the color shift problem of red/pink tint display caused by strong light irradiation.

The second shielding portion B2 is arranged corresponding to the third active portion POL3 and connected to the first shielding portion B1, and the orthographic projection of the second shielding portion B2 on the base substrate covers the orthographic projection of the third active portion POL3 on the base substrate, that is, the second shielding portion B2 is used to shield the channel region of the driving transistor T3. As described above, in the display panel of the present disclosure, the first conductive layer Gate1 can be used as a mask to perform conductor processing on the active layer Polly, that is, the active layer Polly covered by the first conductive layer Gate1 forms the channel region of the transistor, and the area not covered by the first conductive layer Gate1 forms a conductor structure. Because the first conductive layer Gate1 has overlayed the channel region of the active layer Polly, the first metal layer BSM of the present disclosure does not need to overlay the first conductive layer Gate1 at the driving transistor T3, thereby further reducing the area of the first metal layer BSM at the driving transistor T3.

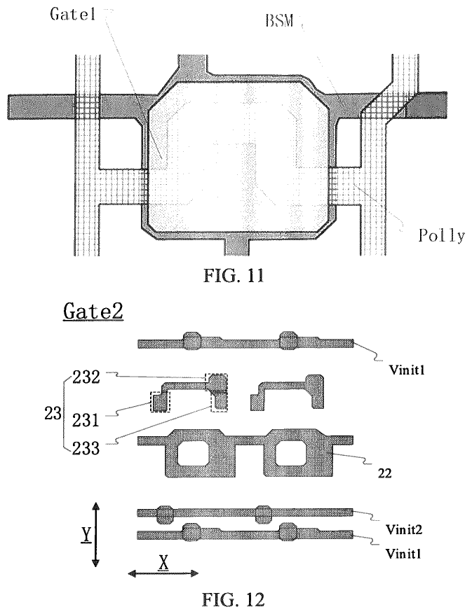

Specifically, as shown in FIG. 7, the first conductive layer Gate1 may include a first conductive block 11, and the orthographic projection of the first conductive block 11 on the base substrate may cover the orthographic projection of the third active portion POL3 on the base substrate, so that the first conductive block 11 may form the gate of the driving transistor T3. In actual products, the first conductive block 11 is usually overlaid on the third active portion POL3, that is, the actual boundary of the first conductive block 11 is larger than the boundary of the third active portion POL3. Taking the stacking diagram shown in FIG. 8 as an example, the boundary shown by the dotted box in the figure is the boundary of the third active portion POL3. It can be seen that because the first conductive block 11 is overlaid on the third active portion POL3, in actual products, the boundary of the third active portion POL3 does not coincide with the boundary of the first conductive block 11 but is located within the boundary of the first conductive block 11. On this basis, the orthographic projection of the second shielding portion B2 on the base substrate may be located within the orthographic projection of the first conductive block 11 on the base substrate, that is, the area covered by the second shielding portion B2 is located within the area covered by the first conductive block 11. FIG. 11 is a local enlarged view illustrating stack of the first metal layer, the active layer and the first conductive layer in the related art. By comparing FIG. 8 and FIG. 11, it can be seen that compared with the related art in which the first metal layer BSM overlays the first conductive block 11 at the driving transistor T3, the first metal layer BSM of this exemplary embodiment can shield the channel region of the driving transistor T3 while further reducing the area of the second shielding portion B2, so that the area of the first metal layer BSM is further reduced, thereby further enhancing the effect of mitigating the color deviation of the display panel caused by strong light exposure.

In some embodiments, the orthographic projection of the second shielding portion B2 on the base substrate may partially overlap with the orthographic projection of the first conductive block 11 on the base substrate. For example, the orthographic projections of the second shielding portion B2 and the first conductive block 11 on the base substrate may have the same shape and some of their side edges are aligned and overlapped, and the remaining side edge of the orthographic projection of the second shielding portion B2 is located within the orthographic projection of the first conductive block 11. This structure also has the effect of reducing the area of the first metal layer and mitigating color deviation.

Continuing to refer to FIG. 8, in an exemplary embodiment, the orthographic projection of the second shielding portion B2 on the base substrate may coincide with the orthographic projection of the first conductive block 11 on the base substrate, that is, the first metal layer BSM is configured to have the same shape as the gate of the driving transistor T3 at the position corresponding to the driving transistor T3 and the corresponding edges thereof overlap with each other. In other words, the first metal layer BSM is configured to have a flush structure with the gate of the driving transistor T3 at the position corresponding to the driving transistor T3, thereby achieving the purpose of reducing the area of the first metal layer BSM at the driving transistor T3.

As shown in FIG. 4 and FIG. 5, in an exemplary embodiment, the shielding unit BSMO may also include a first connecting portion B11 to a fourth connecting portion B14. The first connecting portion B11 is connected to the first shielding portion B1, and the orthographic projection of the first connecting portion B11 on the base substrate extends along the column direction Y. The second connecting portion B12 is connected to a side of the second shielding portion B2 in the column direction Y away from the first shielding portion B1, and the orthographic projection of the second connecting portion B12 on the base substrate extends along the column direction Y. The third connecting portion B13 is connected to a side of the second shielding portion B2 in the row direction X and the orthographic projection thereof on the base substrate extends along the row direction X. The fourth connecting portion B14 is connected to a side of the second shielding portion B2 in the row direction X away from the third connecting portion B13 and the orthographic projection thereof on the base substrate extends along the row direction X.

When referring to that a certain structure A extends along a direction B in the present disclosure, it means that A may include a main part and a secondary part connected to the main part, the main part is a line, a line segment or a strip-shaped body, the main part extends along the direction B, and the length of the main part extending along the direction B is greater than the length of the secondary part extending along another direction.

As shown in FIG. 10, in two adjacent shielding units BSM0 in the row direction X, the third connecting portion B13 in one shielding unit BSM0 is connected to the fourth connecting portion B14 in the other shielding unit BSM0. In two adjacent shielding units BSM0 in the column direction Y, the first connecting portion B11 in one shielding unit BSM0 is connected to the second connecting portion B12 in the other shielding unit BSM0. In this way, the respective shielding units BSM0 form a metal grid structure in the row and column directions. The grid structure can reduce the IR drop of the constant voltage source connected to the first metal layer BSM and reduce the voltage drop loss. In addition, the metal grid structure enables the first metal layer BSM to form an equipotential surface, which can improve the effect of shielding free charges, thereby being beneficial to the characteristics stability of each transistor in the pixel driving circuit, improving the voltage holding rate of the pixel driving circuit, and thus improving the display effect.

In an exemplary embodiment, the first power line VDD of the second source-drain metal layer SD2 can be used to provide a constant voltage source for the first metal layer BSM. Exemplarily, the first power line VDD can be connected to at least one of the first connecting portion B11, the second connecting portion B12, the third connecting portion B13 and the fourth connecting portion B14 in the first metal layer BSM through a via in the non-display area of the display panel, so as to connect the first metal layer BSM to the constant voltage source. For example, the first power line VDD can be arranged circumferentially in the non-display area to form a ring, so that any one or more of the first connecting portion B11 to the fourth connecting portion B14 can be connected to the first power line VDD through a via. Alternatively, in other embodiments, the constant voltage source can also be provided to the first metal layer BSM through other signal lines, for example, the constant voltage source can be provided to the first metal layer BSM through the first initialization signal line Vinit1, or the like, which will not be described in detail here.

Further, as shown in FIG. 5 and FIG. 10, in this exemplary embodiment, the first connecting portion B11 includes a first constituent part B11-1 and a second constituent part B11-2. The first constituent part B11-1 is connected between the first shielding portion B1 and the second constituent part B11-2, and the orthographic projection of the first constituent part B11-1 on the base substrate extends along the row direction. The orthographic projection of the second constituent part B11-2 on the base substrate extends along the column direction, and the orthographic projection of the second constituent part B11-2 on the base substrate is located between the orthographic projections of the fifth active sub-portion POL1-5 and the sixth active sub-portion POL1-6 on the base substrate. The orthographic projection of the first constituent part B11-1 on the base substrate extends along the row direction, so that the second constituent part B11-2 is offset by a certain distance in the row direction, and the orthographic projection of the second constituent part B11-2 on the base substrate passes between the orthographic projections of the fifth active sub-portion POL1-5 and the sixth active sub-portion POL1-6 on the base substrate. In other words, the second constituent part B11-2 does not block the double channels of the first transistor T1 but avoids the double channels of the first transistor T1, thereby reducing the blocking area of the active layer.

Still referring to FIG. 5 and FIG. 10, in this exemplary embodiment, the second connecting portion B12 includes a third constituent part B12-3, a fourth constituent part B12-4 and a fifth constituent part B12-5, where the fourth constituent part B12-4 is connected between the third constituent part B12-3 and the fifth constituent part B12-5, and the orthographic projections of both the third constituent part B12-3 and the fifth constituent part B12-5 on the base substrate extend in the column direction and are staggered in the row direction. The third constituent part B12-3 is connected to the second shielding portion B2, and the fourth constituent part B12-4 is connected between the third constituent part B12-3 and the fifth constituent part B12-5, so that the fifth constituent part B12-5 has a certain interval with the third constituent part B12-3 in the row direction. In other words, the fifth constituent part B12-5 is offset, so that the fifth constituent part B12-5 extends in the column direction to the second constituent part of the next row and is connected thereto, so as to realize the connection between two adjacent shielding units in the column direction.

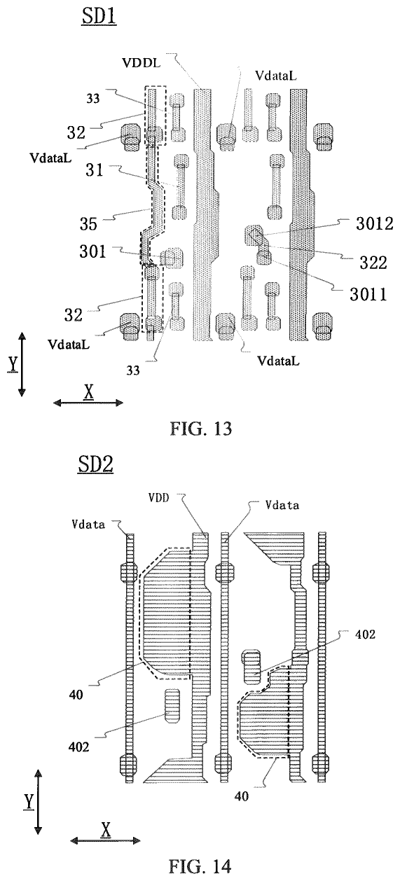

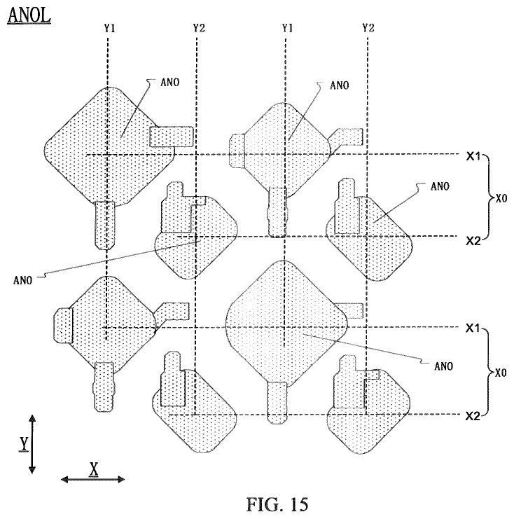

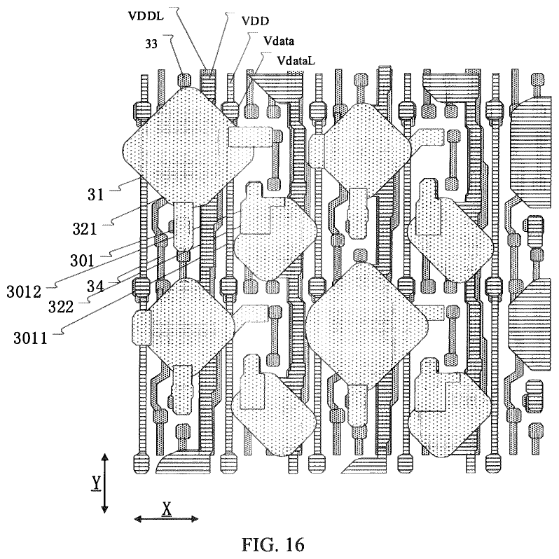

The display panel disclosed herein may also include a first conductive layer Gate1, a second conductive layer Gate2, a first source-drain metal layer SD1, a second source-drain metal layer SD2, and a first electrode layer ANOL, where the base substrate, the first metal layer BSM, the active layer Polly 10, the first conductive layer Gate1, the second conductive layer Gate2, the first source-drain metal layer SD1, the second source-drain metal layer SD2, and the first electrode layer ANOL are stacked in sequence, and an insulating layer(s) may be provided between the above functional layers. FIG. 12 is a structural layout of the second conductive layer in FIG. 4, FIG. 13 is a structural layout of the first source-drain metal layer in FIG. 4, FIG. 14 is a structural layout of the second source-drain metal layer in FIG. 4, FIG. 15 is a structural layout of the first electrode layer in FIG. 4, and FIG. 16 is a stacked layout of the first source-drain metal layer, the second source-drain metal layer, and the first electrode layer in FIG. 4.

As shown in FIG. 4 and FIG. 7, as described above, the first conductive layer Gate1 may include a first conductive block 11, and the orthographic projection of the first conductive block 11 on the base substrate may cover the orthographic projection of the third active portion POL3 on the base substrate, and the first conductive block 11 may be used to form the gate of the driving transistor T3 and the first electrode of the storage capacitor Cst. As described above, according to the present disclosure, the orthographic projection of the first conductive block 11 on the base substrate may be configured to coincide with the orthographic projection of the second shielding portion B2 on the base substrate. In other words, the first conductive block 11 may be configured as flush with the second shielding portion B2 in the first metal layer BSM, thereby reducing the area of the first metal layer BSM and solving the color deviation problem of the display panel caused by strong light exposure.

As shown in FIG. 4 and FIG. 7, in an exemplary embodiment, the first conductive layer Gate1 may further include a first reset signal line Reset n, a gate signal line Gate, an enable signal line EM, and a second reset signal line Reset (n+1). The orthographic projections of the first reset signal line Reset n, the gate signal line Gate, and the enable signal line EM on the base substrate can all extend along the row direction X and be spaced apart in the column direction Y. Moreover, the first reset signal line Reset n and the gate signal line Gate are located on the same side of the first conductive block 11, and the enable signal line EM and the second reset signal line Reset (n+1) are located on the other side of the first conductive block 11. In other words, in the layout structure, the first reset signal line Reset n and the gate signal line Gate are located on the same side of the driving transistor T3, and the enable signal line EM and the second reset signal line Reset (n+1) are located on the other side of the driving transistor T3.

The first reset signal line Reset n can be used to provide the first reset signal terminal in FIG. 1, and the second reset signal line Reset (n+1) can be used to provide the second reset signal terminal in FIG. 1. The orthographic projection of the first reset signal line Reset n on the base substrate can cover the orthographic projections of the fifth active sub-portion POL1-5 and the sixth active sub-portion POL1-6 on the base substrate, so that a partial structure of the first reset signal line Reset n is used to form the gate of the first transistor T1, and the first transistor T1 forms a double-gate structure. The orthographic projection of the second reset signal line Reset (n+1) on the base substrate can cover the orthographic projection of the seventh active portion POL7 on the base substrate, so that a partial structure of the second reset signal line Reset (n+1) is used to form the gate of the seventh transistor T7. In this exemplary embodiment, the second reset signal line Reset (n+1) of a current row can be reused as the first reset signal line Reset n of the next row. By reusing the signal lines, the number of signal lines can be reduced and the layout structure can be simplified.

The gate signal line Gate can be used to provide the gate signal terminal in FIG. 1. In this exemplary embodiment, the second transistor T2 includes dual channels, and the gate signal line Gate can include a main extension portion Gate0 and a secondary extension portion Gate1. The orthographic projection of the main extension portion Gate0 on the base substrate can extend along the row direction X, and the orthographic projection of the secondary extension portion Gate1 on the base substrate can extend along the column direction Y. The orthographic projection of the main extension portion Gate0 on the base substrate can cover the orthographic projection of the first active sub-portion POL2-1 on the base substrate, and the orthographic projection of the secondary extension portion Gate1 on the base substrate can cover the orthographic projection of the second active sub-portion POL2-2 on the base substrate. In this way, a partial structure of the gate signal line Gate can form dual gates of the second transistor T2.

When referring to that a certain structure A extends along a direction B in the present disclosure, it means that A may include a main part and a secondary part connected to the main part, the main part is a line, a line segment or a strip-shaped body, the main part extends along the direction B, and the length of the main part extending along the direction B is greater than the length of the secondary part extending along another direction.

Referring to FIG. 5, FIG. 8 and FIG. 9, in this exemplary embodiment, the first shielding portion B1 includes a first shielding sub-portion B1-1 and a second shielding sub-portion B1-2, where the first shielding sub-portion B1-1 corresponds to the first active sub-portion POL2-1, and the second shielding sub-portion B1-2 corresponds to the second active sub-portion POL2-2. The orthographic projection of the first shielding sub-portion B1-1 on the base substrate extends along the row direction X and has a fifth width d5 in the column direction Y. A first overlapping portion exists between the orthographic projections of the main extension portion Gate0 and the first shielding sub-portion B1-1 on the base substrate, and the first overlapping portion has a seventh width d7 in the column direction Y, where the fifth width d5 is greater than the seventh width d7. The orthographic projection of the second shielding sub-portion B1-2 on the base substrate extends along the column direction Y and has a sixth width d6 in the row direction X. A second overlapping portion exists between the orthographic projections of the secondary extension portion Gate1 and the second active sub-portion POL2-2 on the base substrate, and the second overlapping portion has an eighth width d8 in the row direction X, where the sixth width d6 is greater than the eighth width d8.

Specifically, the first shielding portion B1 shields the first active sub-portion POL2-1 through the first shielding sub-portion B1-1, and shields the second active sub-portion POL2-2 through the second shielding sub-portion B1-2. The width d5 of the first shielding sub-portion B1-1 in the column direction Y is greater than the width d7 of the gate signal line Gate at the corresponding position, that is, the first metal layer BSM overlays the gate signal line Gate at the position corresponding to the first active sub-portion POL2-1, so that the first metal layer BSM not only shields the first active sub-portion POL2-1 but also shields the gate signal line Gate at this position. In an exemplary embodiment, the ratio of the width d7 of the gate signal line Gate at the position corresponding to the first active sub-portion POL2-1 to the width d5 of the first shielding sub-portion B1-1 can be greater than or equal to 50%, for example, it can be 50%, 55%, 60%, 70%, 80%, 90%, or the like.

Similarly, the width d6 of the second shielding sub-portion B1-2 is greater than the width d8 of the secondary extension portion Gate1 of the gate signal line Gate, so that the first metal layer BSM overlays the secondary extension portion Gate1 of the gate signal line Gate. Similarly, the ratio of the width of the secondary extension portion Gate1 of the gate signal line Gate to the width of the second shielding sub-portion B1-2 can be greater than or equal to 50%, for example, it can be 50%, 55%, 60%, 70%, 80%, 90%, or the like.

Further, as shown in FIG. 8, in this exemplary embodiment, a third overlapping portion exists between the orthographic projections of the secondary extension portion Gate1 and the second shielding sub-portion B1-2 on the base substrate, and has a first length L1 in the column direction Y. The orthographic projection of the secondary extension portion Gate1 on the base substrate has a second length L2 in the column direction Y, and the first length L1 is less than the second length L2. That is, a partial structure of the secondary extension portion Gate1 of the gate signal line Gate exceeds the boundary of the second shielding sub-portion B1-2, so that the first metal layer BSM partially shields the secondary extension portion Gate1 of the gate signal line Gate.

The length/width of a certain structure A in a B direction described in the present disclosure can be determined by the following manner. The structure A has a first side and a second side arranged opposite to each other in the B direction, a straight line passing through any first node on the first side and extending along the B direction intersects the second side at the second node, and the distance between the first node and the second node is the length/width of the structure A in the B direction.

The enable signal line EM can be used to provide the enable signal terminal in FIG. 1, and the orthographic projection of the enable signal line EM on the base substrate can respectively cover the orthographic projections of the fifth active portion POL5 and the sixth active portion POL6 on the base substrate. A partial structure of the enable signal line EM can be used to form the gate of the fifth transistor T5, and a partial structure thereof can be used to form the gate of the sixth transistor T6.

In the display panel according to the present disclosure, the first conductive layer Gate1 can be used as a mask to perform conductor processing on the active layer Polly, that is, the active layer Polly covered by the first conductive layer Gate1 forms the channel region of the transistor, and the region thereof not covered by the first conductive layer Gate1 forms a conductor structure. It should be further understood that in actual products, the gate structure of transistor formed by the first conductive layer usually overlays the active portion blocked by it, that is, the gate structure of transistor formed by the first conductive layer in the actual product has a slightly larger orthographic projection area on the base substrate than the orthographic projection area, on the base substrate, of the active portion covered by it. In other words, the orthographic projection area of the active portion on the base substrate is located within the orthographic projection area, on the base substrate, of the gate structure at the corresponding position.

As shown in FIG. 4 and FIG. 12, in an exemplary embodiment, the second conductive layer Gate2 may include a second conductive block 22, where the orthographic projection of the second conductive block 22 on the base substrate may be located on the orthographic projection of the first conductive block 11 on the base substrate, and the second conductive block 22 may be used to form a second electrode of the storage capacitor Cst. The second conductive block 22 has a hollow portion that exposes a part of the first conductive block 11, so that the first conductive block 11 may be connected to the first bridge portion 31 of the first source-drain metal layer SD1 through the hollow portion, thereby connecting the gate of the driving transistor T3 to the second electrode of the first transistor T1 through the first bridge portion 31.

The second conductive block 22 can be connected to the power adapter line VDDL located in the first source-drain metal layer SD1 through a via, and then connected to the first power line VDD in the second source-drain metal layer SD2 through the power adapter line VDDL, thereby connecting the second conductive block 22 to the first power line VDD.

In this exemplary embodiment, two second conductive blocks 22 adjacent to each other in the row direction X are connected to each other, so that the first power line VDD is formed into a grid structure, staggered in rows and columns, through the second conductive blocks 22 extending in the transverse direction. The first power line VDD of the grid structure can reduce the impedance of the first power line VDD, thereby reducing the RC load of the first power line VDD, and further reducing the power consumption of the display panel.

As shown in FIG. 12, in an exemplary embodiment, the second conductive layer Gate2 may also include a first initialization signal line Vinit1 and a second initialization signal line Vinit2. The first initialization signal line Vinit1 and the second initialization signal line Vinit2 may both extend along the row direction X. The first initialization signal line Vinit1 may be used to provide the first initialization signal terminal in FIG. 1. The first initialization signal line Vinit1 may be connected to the third bridge portion 33 of the first source-drain metal layer SD1 through a via, thereby connecting the first electrode of the first transistor T1 to the first initialization signal line Vinit1 through the third bridge portion 33.

The second initialization signal line Vinit2 can be used to provide the second initialization signal terminal in FIG. 1, and the second initialization signal line Vinit2 can be located between the first initialization signal line Vinit1 of the next row and the enable signal line EM of the current row. The second initialization signal line Vinit2 can be connected to the second bridge portion 32 of the first source-drain metal layer SD1 through a via, thereby connecting the first electrode of the seventh transistor T7 to the second initialization signal line Vinit2 through the second bridge portion 32.

As shown in FIG. 12, in an exemplary embodiment, the second conductive layer Gate2 may further include a third conductive block 23, where the third conductive block 23 may be connected to a constant voltage source, for example, may be connected to the first power line VDD through a via. The third conductive block 23 may include a first conductive sub-portion 231, where the orthographic projection of the first conductive sub-portion 231 on the base substrate may extend along the column direction Y. The orthographic projection of the first conductive sub-portion 231 on the base substrate may be located on the orthographic projection of the ninth active portion POL9 on the base substrate, so that the first conductive sub-portion 231 may be used to stabilize the voltage of the ninth active portion POL9 to reduce the leakage of the second transistor T2, thereby preventing the influence of a pixel data voltage change of the adjacent column on this pixel, reducing the voltage fluctuation of the pixel driving circuit driving the transistor T3 in the light-emitting stage, and thus improving the image quality.

The third conductive block 23 may further include a second conductive sub-portion 232, where the orthographic projection of the second conductive sub-portion 232 on the base substrate at least partially overlaps with the orthographic projection of the eleventh active portion POL11 on the base substrate (for example, the width of the second conductive sub-portion 232 in the row direction X may be set to be greater than the width of the eleventh active portion POL11 in the row direction X), so that the second conductive sub-portion 232 can stabilize the voltage of the eleventh active portion POL11, thereby eliminating or reducing the noise influence of the data signal line Vdata or other signal lines on the eleventh active portion POL11. Moreover, since the eleventh active portion POL11 is connected to the gate of the driving transistor T3, the voltage stabilization of the eleventh active portion POL11 can reduce the voltage fluctuation of the driving transistor T3 of the pixel driving circuit during the light-emitting stage.

In addition, the third conductive block 23 may further include a third conductive sub-portion 233, where the third conductive sub-portion 233 is connected to the second conductive sub-portion 232 to connect to a constant voltage source, and the orthographic projection of the third conductive sub-portion 233 on the base substrate can extend along the column direction Y. The orthographic projection of the third conductive sub-portion 233 on the base substrate is located between the orthographic projection of the eleventh active portion POL11 on the base substrate and the orthographic projection of the data signal line Vdata on the base substrate, thereby shielding interference of the alternating voltage of the data signal line Vdata on the eleventh active portion POL11, and thus improving the voltage stabilizing effect of the third conductive block 23 on the eleventh active portion POL11. In addition, it should be understood that there is a conductive connecting portion between the third conductive sub-portion 233 and the second conductive sub-portion 232.

As shown in FIG. 4 and FIG. 13, in an exemplary embodiment, the first source-drain metal layer SD1 may include a power adapter line VDDL, and the orthographic projection of the power adapter line VDDL on the base substrate may extend along the column direction Y. The power adapter line VDDL may be connected to the second conductive block 22 of the second conductive layer Gate2 and the seventeenth active portion POL17 of the active layer Polly through a via(s) on the one hand, and may be connected to the first power line VDD of the second source-drain metal layer SD2 through a via on the other hand, thereby connecting the second electrode of the storage capacitor Cst and the first electrode of the fifth transistor T5 to the first power line VDD. The power adapter line VDDL forms a parallel structure of the first power line VDD, which may reduce the line resistance of the first power line VDD on the one hand, thereby reducing the voltage drop loss on the first power line VDD. On the other hand, when the first power line VDD is broken, a path may be formed through the power adapter line VDDL, thereby avoiding the situation that the pixel driving circuit cannot work normally due to the breakage of the first power line VDD, and thus improving the reliability of the display panel.

As shown in FIG. 13, in an exemplary embodiment, the first source-drain metal layer SD1 may also include a first bridge portion 31, a second bridge portion 32 and a third bridge portion 33. The first bridge portion 31, the second bridge portion 32 and the third bridge portion 33 may all extend along the column direction Y. One end of the first bridge portion 31 may be connected to the first conductive block 11 through a via, and the other end thereof may be connected to the eleventh active portion POL11 through a via, thereby connecting the second electrode of the first transistor T1 to the gate of the driving transistor T3.

One end of the second bridge portion 32 can be connected to the fifteenth active portion POL 15 through a via to connect the first electrode of the seventh transistor T7; and the other end of the second bridge portion 32 can be connected to the second initialization signal line Vinit2 through a via, thereby connecting the first electrode of the seventh transistor T7 to the second initialization signal line Vinit2.

One end of the third bridge portion 33 can be connected to the twelfth active portion POL 12 through a via to connect the first electrode of the first transistor T1, and the other end of the third bridge portion 33 can be connected to the first initialization signal line Vinit1 through a via, thereby connecting the first electrode of the first transistor T1 to the first initialization signal line Vinit1 through the third bridge portion 33.

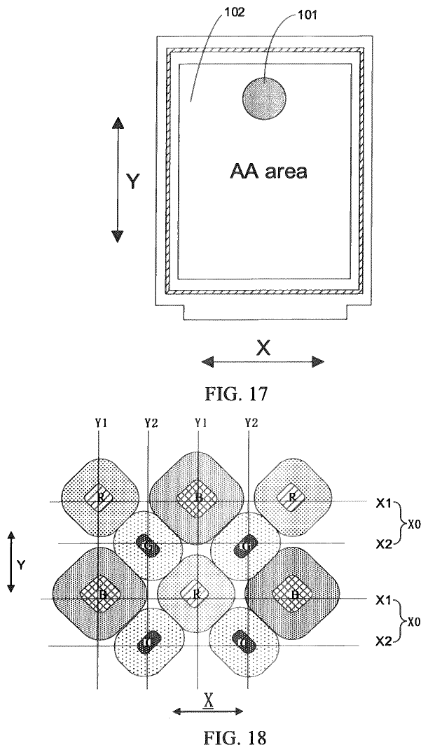

FIG. 17 is a schematic diagram of a display panel according to an embodiment of the present disclosure. As shown in FIG. 17, the display panel of the present disclosure may include a first display area 101 and a second display area 102 at least partially surrounding the first display area 101. The light transmittance of the first display area 101 is greater than that of the second display area 102. The first display area 101 includes a plurality of pixel rows. Exemplarily, the first display area 101 may be an FDC (Full Display with Camera) area, a fingerprint area, or the like; and the second display area 102 may be a normal display area AA. The position of the first display area 101 in the second display area 102 may not be limited, and may be located at the upper part or the lower part of the second display area 102, or may be located at the edge of the second display area 102. In this exemplary embodiment, in a plane parallel to the display substrate, the shape of the first display area 101 may be any one or more of the following: square, rectangular, polygonal, circular, elliptical, etc.; and an optical device such as a fingerprint recognition device, a camera device, or an optical sensor such as a 3D imaging device may be provided in the first display area 101.

It can be understood that the signal line extending in the row direction X is disconnected at the first display area 101, thereby causing the load of the signal line extending in the row direction X to be uneven. As shown in FIG. 13, in this exemplary embodiment, the first source-drain metal layer SD1 may further include a first connection line 35, where the first connection line 35 may be located in the second display area 102, and the orthographic projection of the first connection line 35 on the base substrate may extend along the column direction Y. The first connection line 35 may connect the second bridge 32 in the pixel driving circuit of the current row with the second bridge 32 in the pixel driving circuit of the next row, thereby connecting the second bridge portions 32 in respective pixel driving circuits of the same column, so that the second initialization signal line Vinit2 forms a grid structure staggered in rows and columns, which may reduce the impedance of the second initialization signal line Vinit2, reduce the RC load of the second initialization signal line Vinit2, and help reduce the power consumption. In addition, with the second initialization signal line Vinit2 formed into the grid structure, the disconnected second initialization signal line Vinit2 can be connected, so that the RC load on the second initialization signal line Vinit2 is more uniform, thereby eliminating the problem of uneven display brightness caused by the disconnection of the second initialization signal line Vinit2 and improving display uniformity.

As shown in FIG. 13, in an exemplary embodiment, the first source-drain metal layer SD1 may also include a first adapter portion 301, where the first adapter portion 301 can be connected to the second adapter portion 402 of the second source-drain metal layer SD2 through a via and connected to the eighteenth active portion POL18 through a via, thereby connecting the second electrode of the sixth transistor T6 and the second electrode of the seventh transistor T7 to the first electrode of the light-emitting device. It is worth noting that in this exemplary embodiment, considering that the first electrodes ANO of different sub-pixels are different in size, the offset positions of the first electrodes ANO in different sub-pixels relative to the sixth transistor T6 and the seventh transistor T7 in the pixel driving circuit will be different. Exemplarily, the display panel may include a first sub-pixel R, a second sub-pixel G, and a third sub-pixel B. The first sub-pixel may be, for example, an R sub-pixel, the second sub-pixel may be, for example, a G sub-pixel, and the third sub-pixel may be, for example, a B sub-pixel. Alternatively, in other embodiments, the sub-pixels may also have other arrangements. This exemplary embodiment only takes the first sub-pixel as an R sub-pixel, the second sub-pixel as a G sub-pixel, and the third sub-pixel as a B sub-pixel as an example for exemplary description. The area of the first electrode ANO-R in the first sub-pixel R is the largest, and the area of the first electrode ANO in the second sub-pixel G is the smallest. The first sub-pixel R and the third sub-pixel B can be located in the first pixel column, and the second sub-pixel G can be located in the second pixel column. The first pixel columns and the second pixel columns are alternately distributed in the row direction. In the first pixel column, the first adapter portion 301 can be directly connected to the second adapter portion 402 of the second source-drain metal layer SD2 through a via to connect the first electrode ANO at the corresponding position. In the second pixel column, the first source-drain metal layer SD1 may also include a connecting sub-portion 322, the first adapter portion 301 may include a first adapter sub-portion 3011 and a second adapter sub-portion 3012, and the first adapter sub-portion 3011 and the second adapter sub-portion 3012 may be connected through the connecting sub-portion. The second adapter portion 402 may be bent to connect the second adapter sub-portion 3012 located below the first electrode ANO in the second pixel column to the first adapter sub-portion 3011 located above the second electrode of the sixth transistor T6.

As shown in FIG. 13, in an exemplary embodiment, the first source-drain metal layer SD1 may also include a data adapter part VdataL, which may be connected to the fourteenth active portion POL 14 through a via to connect the second electrode of the fourth transistor T4, and connected to the data signal line Vdata of the second source-drain metal layer SD2 through a via, thereby connecting the second electrode of the fourth transistor T4 to the data signal line Vdata.

As shown in FIG. 4 and FIG. 14, in an exemplary embodiment, the second source-drain metal layer SD2 may include a first power line VDD and a data signal line Vdata. The orthographic projections of the first power line VDD and the data signal line Vdata on the base substrate may extend along the column direction Y, where the first power line VDD can be used to provide the first power terminal in FIG. 1, and the first power line VDD can be connected to the power adapter line VDDL of the first source-drain metal layer SD1 through a via, thereby connecting the second electrode of the storage capacitor Cst to the first electrode of the fifth transistor T5 through the power adapter line VDDL.

The data signal line Vdata can be used to provide the data signal terminal in FIG. 1, and the data signal line Vdata can be connected to the data adapter portion VdataL of the first source-drain metal layer SD1 through a via, thereby connecting the data signal line Vdata to the second electrode of the fourth transistor T4 through the data adapter portion VdataL.

As shown in FIG. 14, in an exemplary embodiment, the second source-drain metal layer SD2 may also include a second adapter portion 402, which may be connected to the first adapter portion 301 of the first source-drain metal layer SD1 through a via and to the first electrode ANO of the first electrode layer ANOL through a via, thereby connecting the second electrode of the sixth transistor T6 and the second electrode of the seventh transistor T7 to the first electrode ANO of the light-emitting device.

As shown in FIG. 14, in an exemplary embodiment, the second source-drain metal layer SD2 may also include an electrode planarization portion 40. The electrode planarization portion 40 may be connected to the first power line VDD, and the electrode planarization portion 40 may be located below the first electrode ANO, so as to planarize the first electrode ANO below the first electrode ANO. For example, the orthographic projection of the first electrode ANO on the base substrate may cover the orthographic projection of the electrode planarization portion 40 on the base substrate, thereby preventing the first electrode ANO from tilting, and thus ensuring that the light-emitting device can display normally.

As shown in FIG. 15, in an exemplary embodiment, the first electrode layer ANOL may include a plurality of first electrodes ANO, and the first electrode ANO may be, for example, an anode of a light-emitting device. Alternatively, in other embodiments, the first electrode ANO may also be a cathode of the light-emitting device, which is not particularly limited here. The present disclosure only takes the first electrode ANO as an anode of the light-emitting device for exemplary description.

The first electrode ANO may be connected to the second adapter portion 402 of the second source-drain metal layer SD2 through a via, thereby connecting the first electrode ANO of the light-emitting device to the second electrode of the sixth transistor T6 and the second electrode of the seventh transistor T7 through the second adapter portion 402.

The display panel disclosed herein may include a first sub-pixel, a second sub-pixel and a third sub-pixel, with each sub-pixel being arranged in a one-to-one correspondence with a pixel driving circuit. The first electrode of the first sub-pixel and the first electrode of the third sub-pixel are located in a first pixel column, the first electrode of the second sub-pixel is located in a second pixel column, and the first pixel columns and the second pixel columns are alternately distributed in the row direction.

Exemplarily, FIG. 18 is a schematic arrangement diagram of the sub-pixels according to an embodiment of the present disclosure. As shown in FIG. 18, the first sub-pixel may be an R sub-pixel, the second sub-pixel may be a G sub-pixel, and the third sub-pixel may be a B sub-pixel. A pixel unit includes a first sub-pixel R, a second sub-pixel G and a third sub-pixel B. The first sub-pixel R and the third sub-pixel B of each pixel unit are located in the same row, namely the first sub-pixel row X1; and the second sub-pixel G of each pixel unit is located in the same row to form a second sub-pixel row X2. The first sub-pixel R and the third sub-pixel B are located in the first pixel column Y1, and the second sub-pixel G is located in the second pixel column Y2, thereby forming a pixel arrangement of RGBG.

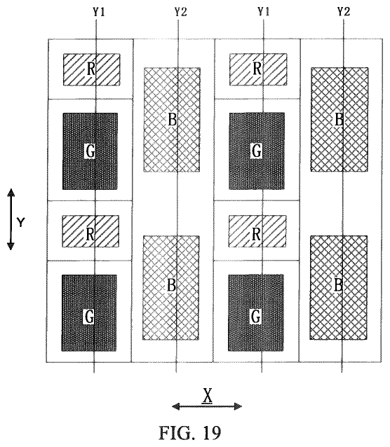

FIG. 19 is a schematic arrangement diagram of the sub-pixels according to another embodiment of the present disclosure. As shown in FIG. 19, the first sub-pixel may be an R sub-pixel, the second sub-pixel may be a B sub-pixel, and the third sub-pixel may be a G sub-pixel. In this arrangement, the first sub-pixel R and the third sub-pixel G are located in the first pixel column Y1, the second sub-pixel B is located in the second pixel column Y2, and the first pixel columns Y1 and the second pixel columns Y2 are alternately distributed in the row direction, thereby forming a pixel arrangement of RGB. It should be understood that in other embodiments, the sub-pixels may also have other arrangements, as long as the sub-pixels form two pixel columns alternately arranged in the row direction, they are applicable to the disclosed solution, and are not listed here one by one.

Referring to FIG. 18, FIG. 19 and FIG. 15, in the same column of sub-pixels, the first electrode ANO of the first sub-pixel and the first electrode ANO of the third sub-pixel are located in the first pixel column, the first electrode ANO of the second sub-pixel is located in the second pixel column, and the first pixel columns and the second pixel columns are alternately distributed in the row direction X. Followings take only an example in which the first sub-pixel is an R sub-pixel, the second sub-pixel is a G sub-pixel, the third sub-pixel is a B sub-pixel, and the first electrode of the first sub-pixel is represented as ANO-R, the first electrode of the second sub-pixel is represented as ANO-G, and the first electrode of the third sub-pixel is represented as ANO-B, so as to further explain the solution of the present disclosure in conjunction with the pixel electrode arrangement shown in FIG. 15. It should be understood that the sub-pixels can also eliminate or reduce the problem of display color deviation under strong light illumination based on the inventive concept of the present disclosure in other arrangements, which will not be listed one by one in this disclosure.

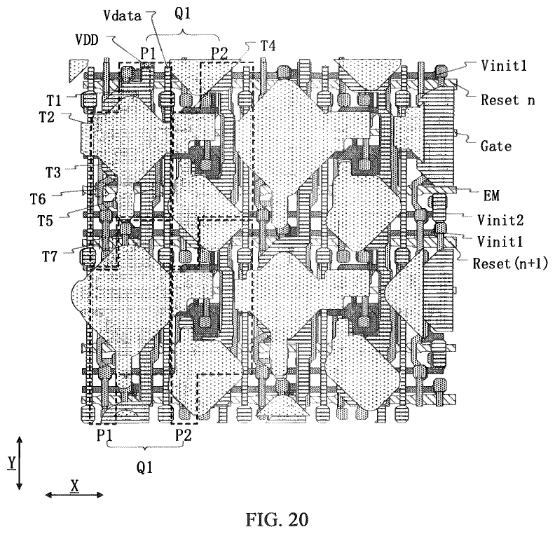

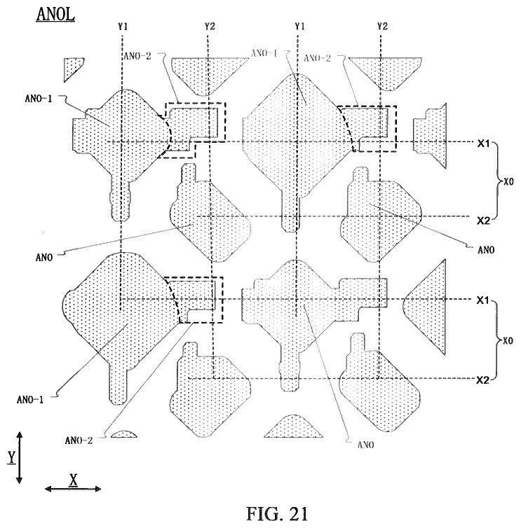

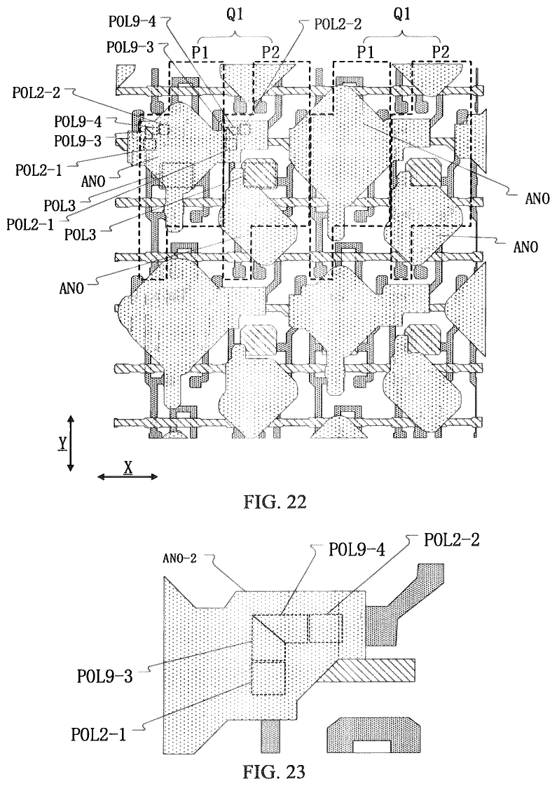

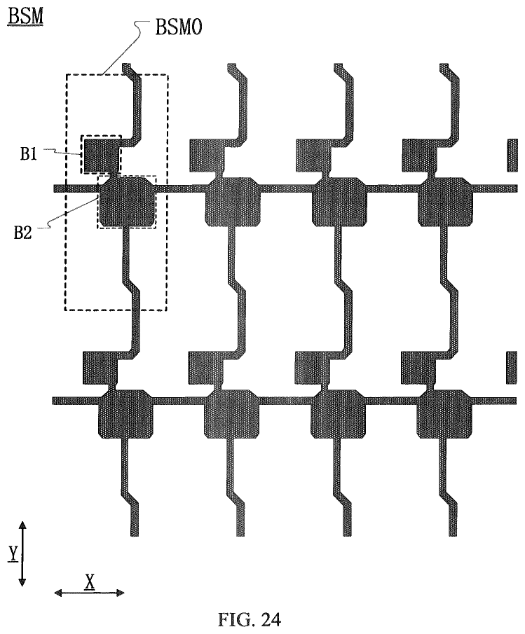

On the basis of the above embodiment, FIG. 20 is a structural layout of a display panel according to another embodiment of the present disclosure; FIG. 21 is a structural layout of the first electrode layer in FIG. 20; FIG. 22 is a stacked layout of the active layer, the first conductive layer and the first electrode layer in FIG. 20; and FIG. 23 is a partial enlarged view corresponding to the first electrode of the first pixel driving circuit extending to the second transistor of the second pixel driving circuit in FIG. 22. It should be understood that the layout structure shown in FIG. 20 can have all the features of the first metal layer BSM, the active layer Polly, the first conductive layer Gate1, the second conductive layer Gate2, the first source-drain metal layer SD1 and the first electrode layer ANOL in the layout structure shown in FIG. 4, which will not be described in detail here. In addition, the first metal layer BSM can also have other structures. For example, as shown in FIG. 24, the first metal layer BSM can also shield, at the second transistor T2, the conductor structure T2M between the double channels of the second transistor T2. In other words, the first shielding portion B1 no longer has a gap BO, but completely shields the channel region of the second transistor T2 and the conductor structure T2M between the double channels. This exemplary embodiment does not specifically limit the structure of the first metal layer BSM.

In an exemplary embodiment, the second metal layer may be the first electrode layer ANOL, that is, the metal of the first electrode layer ANOL is used to shield the second transistor T2 and the driving transistor T3.

As shown in FIG. 20 and FIG. 21, the display panel includes a plurality of first repeating units Q1 arrayed in the row and column directions, where the first repeating unit Q1 includes a first pixel driving circuit P1 and a second pixel driving circuit P2 adjacently arranged in the row direction X. The figure shows four first repeating units Q1 in two rows and four columns. In this exemplary embodiment, the first pixel driving circuit P1 may be arranged in a one-to-one correspondence with the first sub-pixel R and the third sub-pixel B, and the second pixel driving circuit P2 may be arranged in a one-to-one correspondence with the second sub-pixel G, that is, the pixel driving circuits driving the first sub-pixel R and the third sub-pixel B are both the first pixel driving circuit P1, and the pixel driving circuit driving the second sub-pixel G is the second pixel driving circuit P2.

Referring to FIG. 21, FIG. 22 and FIG. 23, in any first repeating unit Q1, the orthographic projection of the first electrode ANO connected to the first pixel driving circuit Pl on the base substrate covers the orthographic projections of the second active portion POL2 and the ninth active portion POL9 in the first pixel driving circuit P1 on the base substrate and overlaps with the orthographic projection of the third active portion POL3 on the base substrate, and also at least partially overlaps with the orthographic projections of the second active portion POL2 and the ninth active portion POL9 in the second pixel driving circuit P2 on the base substrate; the orthographic projection of the first electrode ANO connected to the second pixel driving circuit P2 on the base substrate partially overlaps with the orthographic projection of the third active portion POL3 in the second pixel driving circuit P2 on the base substrate.

Exemplarily, the orthographic projection of the first electrode ANO in the first sub-pixel R on the base substrate may cover the orthographic projection of the third active portion POL3 in the corresponding pixel driving circuit on the base substrate, and may also cover the orthographic projections of the second active portion POL2 and the ninth active portion POL9 in the adjacent second pixel driving circuit P2 on the base substrate. In other words, the first electrode ANO of the first sub-pixel R completely shields the second transistor T2 and the driving transistor T3 in the corresponding pixel driving circuit, and can also completely shield the second transistor T2 in the adjacent driving circuit, thereby improving the shielding effect on the active layer Polly. It should be understood that the pixel driving circuit corresponding to the first electrode ANO described in the present disclosure refers to the pixel driving circuit connected to the first electrode.

The orthographic projection of the first electrode ANO in the third sub-pixel B on the base substrate may cover the orthographic projections of the second active portion POL2 and the ninth active portion POL9 in the corresponding pixel driving circuit on the base substrate, and may partially overlap with the orthographic projection of the third active portion POL3 on the base substrate. For example, the ratio of the overlapping area to the area of the third active portion POL3 can be greater than or equal to 75%, such as 75%, 80%, 85%, 90%, 95%, or the like; that is, the first electrode ANO in the third sub-pixel B can completely shield the second transistor T2 in the corresponding pixel driving circuit and partially shield the driving transistor T3. Also, the orthographic projection of the first electrode ANO in the third sub-pixel B on the base substrate may cover the orthographic projection of the ninth active portion POL9 in the adjacent second pixel driving circuit P2 on the base substrate, and partially overlap with the orthographic projection of the second active portion POL2 on the base substrate. For example, the ratio of the overlapping area to the area of the second active portion POL2 can be greater than or equal to 50%, such as 50%, 60%, 75%, 80%, 85%, 90%, 95%, or the like; that is, the first electrode ANO of the third sub-pixel B can also partially shield the second transistor T2 in the pixel driving circuit of the adjacent second sub-pixel G. Alternatively, in some embodiments of the present disclosure, the orthographic projection of the first electrode ANO in the third sub-pixel B on the base substrate can also cover the orthographic projection of the third active portion POL3 in the corresponding pixel driving circuit on the base substrate and the orthographic projection of the second active portion POL2 in the pixel driving circuit of the adjacent second sub-pixel on the base substrate, that is, the first electrode ANO of the third sub-pixel B can also completely shield the driving transistor T3 in the corresponding pixel driving circuit and the second transistor T2 in the adjacent pixel driving circuit.

In an exemplary embodiment, as shown in FIG. 19 and FIG. 22, the first electrode ANO in the first sub-pixel R and the third sub-pixel B includes a main portion ANO-1 and an additional portion ANO-2, where the additional portion ANO-2 is connected to a side of the main portion ANO-1 along the row direction X, and the additional portion extends along the row direction X to the second transistor T2 of the second pixel driving circuit P2 in the same repeating unit. In the same first repeating unit Q1, the main portion ANO-1 of the first sub-pixel R has its orthographic projection on the base substrate covering the orthographic projections of the second active portion POL2, the third active portion POL3, and the ninth active portion POL9 in the first pixel driving circuit P1 on the base substrate, and also covers the orthographic projections of the first active sub-portion POL2-1 and the third active sub-portion POL9-3 in the second pixel driving circuit P2 on the base substrate. The orthographic projection of the additional portion ANO-2 in the first sub-pixel R on the base substrate covers the orthographic projections of the second active sub-portion POL2-2 and the fourth active sub-portion POL9-4 in the second pixel driving circuit P2 on the base substrate. That is, the first electrode ANO of the first sub-pixel R shields, through its main portion ANO-1, the second transistor T2, the driving transistor T3 in the corresponding pixel driving circuit, and the first channel region of the second transistor T2 in the adjacent pixel driving circuit; and shields, through its additional portion ANO-2, the conductive structure T2M and the second channel region of the second transistor T2 in the adjacent pixel driving circuit.

In the same first repeating unit Q1, the main portion ANO-1 of the first electrode ANO in the third sub-pixel B has its orthographic projection on the base substrate covering the orthographic projections of the second active portion POL2 and the ninth active portion POL9 in the first pixel driving circuit P1 on the base substrate, and overlaps with the orthographic projection of the third active portion POL3 on the base substrate; the additional part ANO-2 of the first electrode ANO in the third sub-pixel B has its orthographic projection on the base substrate covering the orthographic projections of the second active sub-portion POL2-2 and the ninth active portion POL9 in the second pixel driving circuit P2 on the base substrate, and partially overlaps with the orthographic projection of the first active sub-portion POL2-1 on the base substrate. In other words, the first electrode ANO of the third sub-pixel B, through its main portion ANO-1, can completely shield the second transistor T2 in the corresponding pixel driving circuit and partially shield the driving transistor T3 in the corresponding pixel driving circuit; and the first electrode ANO of the third sub-pixel B can partially shield the second transistor T2 in the adjacent driving circuit through its additional part ANO-2. Alternatively, in some embodiments, the orthographic projection of the first electrode ANO in the third sub-pixel on the base substrate may also cover the orthographic projection of the third active portion POL3 in the corresponding pixel driving circuit on the base substrate and the orthographic projection of the first active sub-portion in the adjacent pixel driving circuit on the base substrate. In other words, the first electrode ANO of the third sub-pixel may also completely shield the driving transistor T3 in the corresponding pixel driving circuit and the second transistor T2 in the adjacent pixel driving circuit.

This exemplary embodiment is equivalent to enlarging the first electrodes ANO-B of the first sub-pixel R and the third sub-pixel B, so that both the first electrode ANO-R of the first sub-pixel R and the first electrode ANO-B of the third sub-pixel B shield the second transistors T2 in the present pixel driving circuit and the adjacent pixel driving circuit for driving the second sub-pixel G, thereby effectively avoiding the influence of external light sources, and mitigating or eliminating the color shift problem caused by strong light exposure. In this exemplary embodiment, the additional portion ANO-2 of the first electrode ANO-R in the first sub-pixel R is smaller than the additional portion ANO-2 of the first electrode ANO-B in the third sub-pixel B, that is, the enlarged area of the first electrode ANO-B in the third sub-pixel B is larger than the enlarged area of the first electrode ANO-R in the first sub-pixel R, so that the first electrode ANO-B of the third sub-pixel B can effectively shield the second transistor T2 in the adjacent pixel driving circuit for driving the second sub-pixel G.

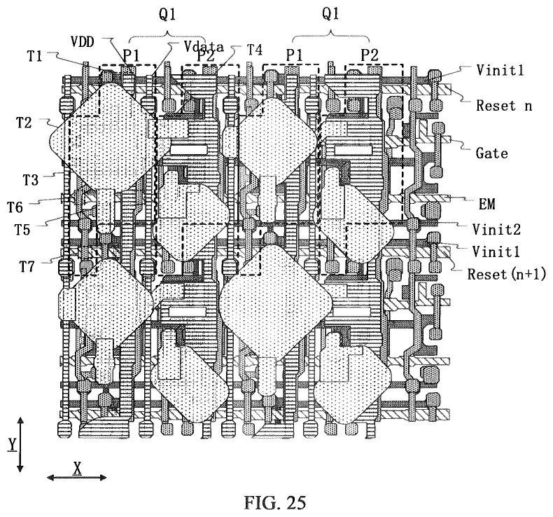

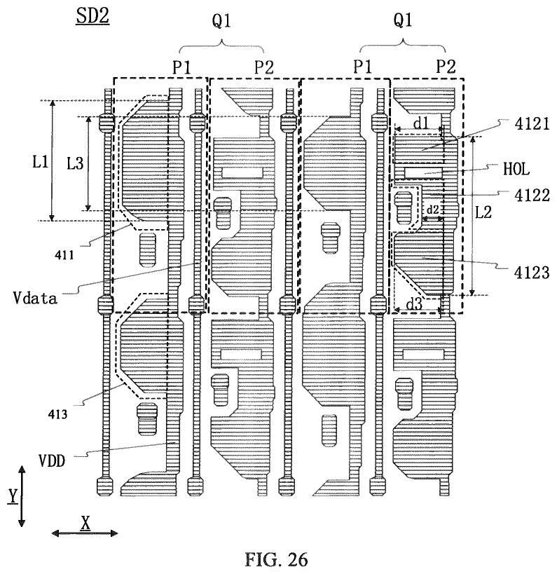

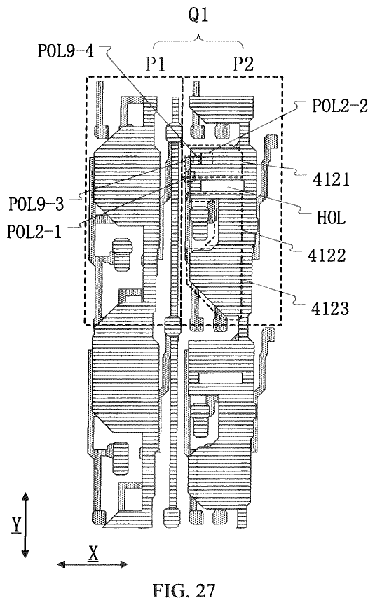

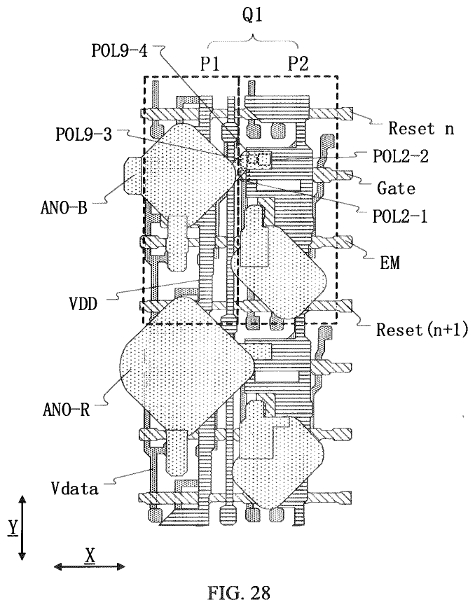

On the basis of the above embodiments, FIG. 25 is a structural layout of a display panel according to another embodiment of the present disclosure, FIG. 26 is a structural layout of the second source-drain metal layer in FIG. 25, FIG. 27 is a stacked layout of the active layer and the second source-drain metal layer in FIG. 25, and FIG. 28 is a stacked layout of the active layer, the second source-drain metal layer and the first electrode layer in FIG. 25. It should be understood that the layout structure shown in FIG. 25 may have all the features of the first metal layer BSM, the active layer Polly, the first conductive layer Gate1, the second conductive layer Gate2, the first source-drain metal layer SD1 and the first electrode layer ANOL in the above embodiments, which will not be described in detail here.

As described above, the second source-drain metal layer SD2 may include an electrode planarization portion 40. This exemplary embodiment may utilize the electrode planarization portion 40 in conjunction with the first electrode ANO to shield the second transistor T2 and the driving transistor T3, thereby shielding light incident from the display side to the second transistor T2 and the driving transistor T3.

As shown in FIG. 25 to FIG. 28, in an exemplary embodiment, the electrode planarization portion 40 in the second source-drain metal layer SD2 may include a first planarization part 411, a second planarization part 412, and a third planarization part 413, where the first planarization part 411 is arranged in a one-to-one correspondence with the first sub-pixel R, the second planarization part 412 is arranged in a one-to-one correspondence with the second sub-pixel G, and the third planarization part 413 is arranged in a one-to-one correspondence with the third sub-pixel B. In other words, the second planarization part 412 is located in the second pixel driving circuit P2 and, in the corresponding repeating unit, the first planarization part 411 and the third planarization part 413 are both located in the first pixel driving circuit P1. The first planarization part 411 and the third planarization part 413 are located in the first pixel column, and the second planarization part 412 is located in the second pixel column.

The display panel may include a plurality of first repeating units Q1 arranged in an array along the row and column directions. The first repeating unit Q1 includes a first pixel driving circuit P1 and a second pixel driving circuit P2 adjacently arranged in the row direction X.

As shown in FIG. 26 to FIG. 28, the second planarization part 412 may include a first extension 4121, a second extension 4122, and a third extension 4123 sequentially connected in the column direction Y. In the same first repeating unit Q1, the orthographic projection of the first extension 4121 on the base substrate may partially overlap with as the orthographic projection, on the base substrate, of the second active portion POL2 and the ninth active portion POL9 in the same pixel driving circuit. For example, it may cover the orthographic projections, on the base substrate, of the second active sub-portion POL2-2 and the fourth active sub-portion POL9-4 in the same pixel driving circuit, and partially overlap with the orthographic projection of the first active sub-portion POL2-1 and the third active sub-portion POL9-3 on the base substrate, where the ratio of the overlapping area to the area of the first active sub-portion POL2-1 may be, for example, greater than or equal to 5%, such as 5%, 10%, 20%, 25%, 30%, 35%, 40%, 50%, 60%, 70%, or the like. Similarly, the ratio of the overlapping area between the first active sub-portion 4121 and the first extension 4121 to the area of the first extension 4121 can be greater than or equal to 5%. The orthographic projection of the second extension 4122 on the base substrate partially overlaps with the orthographic projection, on the base substrate, of the third active portion POL3 in the same pixel driving circuit and, for example, the ratio of the overlapping area to the area of the third active portion POL3 can be greater than or equal to 5%, such as 5%, 10%, 20%, 25%, 30%, 35%, 40%, 50%, 60%, 70%, or the like. The orthographic projection of the third extension 4123 on the base substrate is located within the orthographic projection, on the base substrate, of the first electrode ANO in the corresponding sub-pixel. Specifically, in the second sub-pixel G, because the second transistor T2 and the driving transistor T3 are not in the pixel opening area, this exemplary embodiment is equivalent to extending, in the column direction, the electrode planarization portion 40 in the pixel driving circuit corresponding to the second sub-pixel G, so that the electrode planarization portion 40 in the second sub-pixel G can shield part of the second transistor T2 and part of the driving transistor T3 in this pixel driving circuit, thereby improving the shielding effect on the second transistor T2 and the driving transistor T3, and further mitigating the color deviation problem caused by strong light exposure.

Further, as shown in FIG. 28, in any first repeating unit Q1, the orthographic projections of the first electrode ANO-R in the first subpixel R and the first electrode ANO-B in the third subpixel B on the base substrate cover the orthographic projections, on the base substrate, of the second active portion POL2, the ninth active portion POL9 and the third active portion POL3 in the corresponding first pixel driving circuit P1. The orthographic projection of the first electrode ANO-R in the first subpixel R on the base substrate also covers the orthographic projections, on the base substrate, of the second active portion POL2 and the ninth active portion POL9 in the corresponding second pixel driving circuit P2. The orthographic projection of the first electrode ANO-B in the third subpixel B on the base substrate at least partially overlaps with the orthographic projections, on the base substrate, of the second active portion POL2 and the ninth active portion POL9 in the corresponding second pixel driving circuit P2; for example, it may cover the orthographic projections, on the base substrate, of the second active sub-portion POL2-2 and the ninth active portion POL9 in the corresponding second pixel driving circuit P2. In other words, the first electrode ANO-R of the first sub-pixel R not only shields the second transistor T2 and the driving transistor T3 in its own pixel driving circuit, but also shields the second transistor T2 corresponding to the second sub-pixel G adjacent in the row direction X, thereby compensating for the inability of the electrode planarization portion 40 in the second sub-pixel G to completely shield the second transistor T2, further improving the suppression effect of the pixel driving circuit on leakage current, and mitigating the color deviation problem of the display panel under strong light irradiation. The area of the first electrode ANO-B in the third sub-pixel B is relatively small but, in addition to shielding the second transistor T2 and the driving transistor T3 in its own pixel driving circuit, can also partially shield the second transistor T2 corresponding to the second sub-pixel G adjacent in the row direction X, which can also mitigate the color deviation problem caused by strong light irradiation.

As shown in FIG. 26 and FIG. 27, in an exemplary embodiment, in the second planarization part 412, there is a hollow portion HOL between the first extension 4121 and the second extension 4122, where the hollow portion HOL is used to expose at least part of the gap between the second transistor T2 and the driving transistor T3. It can be known that a transistor is usually composed of a plurality of structures distributed in two or more functional film layers. Accordingly, the area, on the base substrate, covered by the entire structures distributed in multiple functional film layers for forming a transistor is the area occupied by the transistor. Therefore, the gap between the second transistor T2 and the driving transistor T3 described in the present disclosure can be specifically understood as: the entire structures distributed in multiple functional film layers for forming the second transistor T2 covers a first area on the base substrate, and the entire structures distributed in multiple functional film layers for forming the driving transistor T3 covers a second area on the base substrate, and a blank area between the first area and the second area is the gap between the second transistor T2 and the driving transistor T3.

In this exemplary embodiment, the second planarization part 412 exposes the gap between the second transistor T2 and the driving transistor T3, so as to ensure the light transmittance of the first display area 101, that is, avoid the light transmittance of the first display area 101 being less than a design value due to the complete shielding of metal. For example, by exposing the gap between the second transistor T2 and the driving transistor T3 through the second planarization part 412, the light transmittance of the first display area 101 can be greater than or equal to 2%, so as to meet the light transmission requirement of the first display area 101. In addition, by exposing the gap between the second transistor T2 and the driving transistor T3 through the second planarization part 412, the pixel capacitance of the second sub-pixel G can be adjusted, so that the pixel capacitance between different sub-pixels is more uniform.

As shown in FIG. 26, in this exemplary embodiment, the orthographic projection of the first extension 4121 on the base substrate has a first width d1 in the row direction X, the orthographic projection of the second extension 4122 on the base substrate has a second width d2 in the row direction X, and the orthographic projection of the third extension 4123 on the base substrate has a third width d3 in the row direction X, where the second width d2 is smaller than the first width d1, and is smaller than the third width d3. In other words, the width of the second planarization part 412 in the row direction X is wider at both ends and narrower in the middle. The third extension 4123 is located below the first electrode ANO of the second sub-pixel G, and is to support the first electrode ANO in the row direction X, thereby planarizing the first electrode ANO. The second extension 4122 is located below the driving transistor T3, and the width of the second extension 4122 in the row direction X can be contracted to avoid the first electrode ANO adapter portion in the same layer. In this exemplary embodiment, the orthographic projection of the second extension 4122 on the base substrate at least overlaps with the orthographic projection of the third active portion POL3 on the base substrate, that is, the second extension 4122 can shield part of the channel region of the driving transistor T3. The first extension 4121 extends to the bottom of the second transistor T2, and can shield the second transistor T2. The first extension 4121 also shields the conductive structure T2M connected between the double channels of the second transistor T2, thereby increasing the shielding area of the second transistor T2 and mitigating the color shift phenomenon caused by the generation of photogenerated carriers due to strong light irradiation. It is worth noting that the width of a certain extension portion M in a direction C described in the present disclosure refers to the width of the main part of the extension portion M in the direction C.

As shown in FIG. 28, in an exemplary embodiment, the orthographic projection of the first planarization part 411 on the base substrate may partially overlap with the orthographic projections, on the base substrate, of the second active portion POL2, the third active portion POL3 and the ninth active portion POL9 in the same pixel driving circuit. For example, it may cover the orthographic projections, on the base substrate, of the second active sub-portion POL2-2, the fourth active sub-portion POL9-4 and the third active portion POL3 in the same pixel driving circuit, and may partially overlap with the orthographic projections of the first active sub-portion POL2-1 and the third active sub-portion POL9-3 on the base substrate. The electrode planarization portion 40 is to avoid the data signal line Vdata on the left side in the same layer to avoid adhesion with the data signal line Vdata, so the electrode planarization portion 40 cannot completely shield the second transistor T2. Similarly, the orthographic projection of the third planarization part 413 on the base substrate may partially overlap with the orthographic projections, on the base substrate, of the second active portion POL2, the third active portion POL3 and the ninth active portion POL9 in the same pixel driving circuit. For example, it may cover the orthographic projections, on the base substrate, of the second active sub-portion POL2-2 and the fourth active sub-portion POL9-4 in the same pixel driving circuit, and at least partially overlap with the orthographic projection of the third active portion POL3 on the base substrate. In other words, the first electrode ANO-B of the third sub-pixel B is also to avoid the data signal line Vdata and cannot completely shield the second transistor T2.

The third active portion POL3 and the first electrode ANO-B of the third subpixel B have their orthographic projections on the base substrate at least partially overlapping with each other. For example, the overlapping area may be greater than or equal to 85%, that is, the first electrode ANO-B of the third subpixel B can effectively shield most of the structure of the driving transistor T3, thereby improving the effect of mitigating the color deviation. In addition, it can be understood that the orthographic projections of the first electrode ANO-R in the first sub-pixel R and the first electrode ANO-B in the third sub-pixel B on the base substrate both cover the orthographic projection, on the base substrate, of the first planarization part 411 in the corresponding pixel driving circuit, so that the electrode planarization portion 40 can planarize and support the first electrode ANO located thereon.

As shown in FIG. 26, in an exemplary embodiment, the orthographic projection of the first electrode ANO-R in the first sub-pixel R on the base substrate has a first area, the orthographic projection of the first electrode ANO in the second sub-pixel G on the base substrate has a second area, and the orthographic projection of the first electrode ANO-B in the third sub-pixel B on the base substrate has a third area, where the first area>the third area>the second area. The first planarization part 411 has a first extension length L1 in the column direction Y, the second planarization part 412 has a second extension length L2 in the column direction Y, and the third planarization part 413 has a third extension length L3 in the column direction Y, where the second extension length L2>the first extension length L1>the third extension length L3. In other words, the length of the electrode planarization portion 40 in the first sub-pixel R and the third sub-pixel B remains unchanged, while the electrode planarization portion 40 in the second sub-pixel G is lengthened, so that the electrode planarization portion 40 in the second sub-pixel G is the longest, thereby enabling the electrode planarization portion 40 in the second sub-pixel G to partially shield the second transistor T2 of the second sub-pixel G. For the entire display panel, the shielding area of the second transistor T2 and the driving transistor T3 in the driving backplane is increased, thereby reducing photogenerated carriers and reducing leakage current, and thus solving the color deviation problem of the display panel caused by strong light exposure.

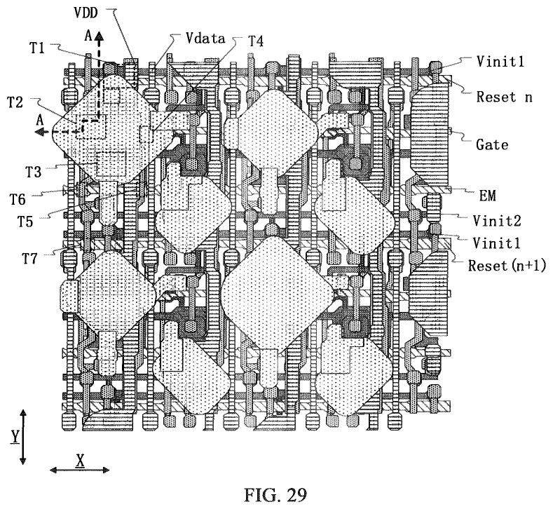

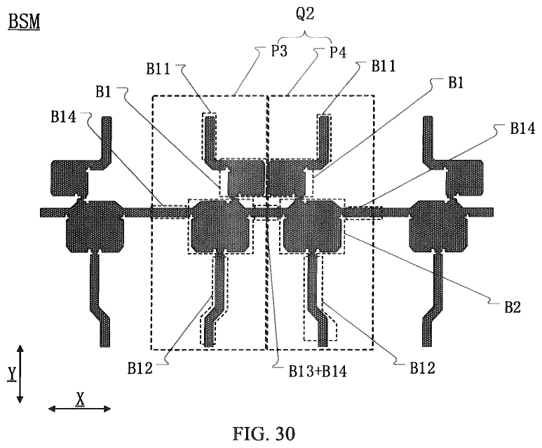

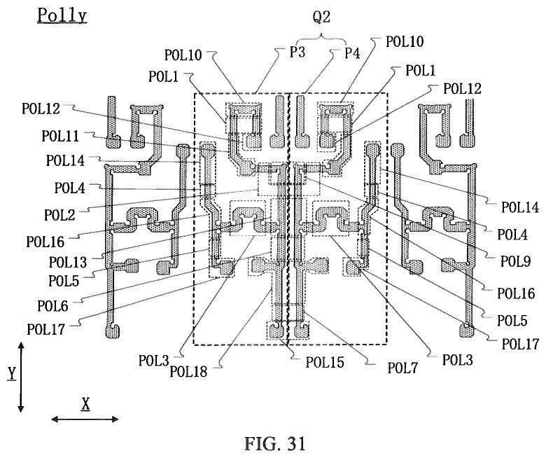

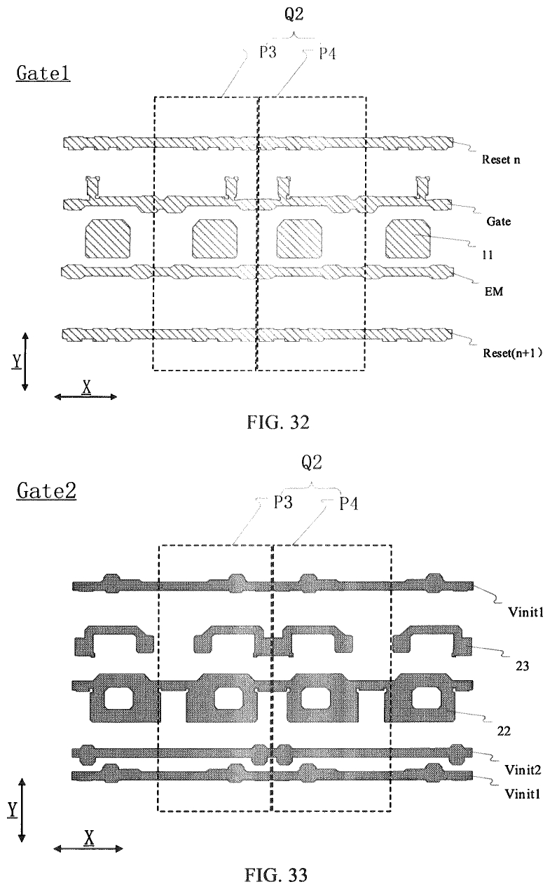

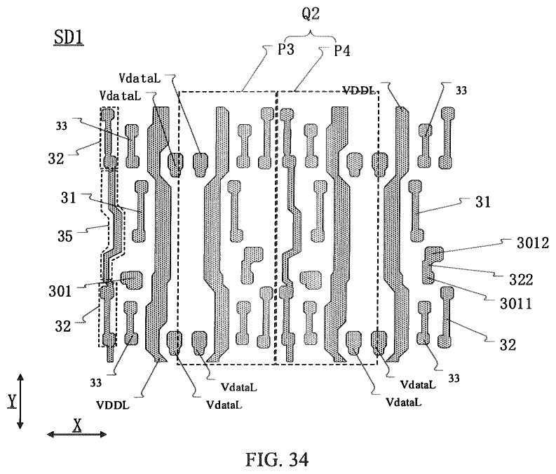

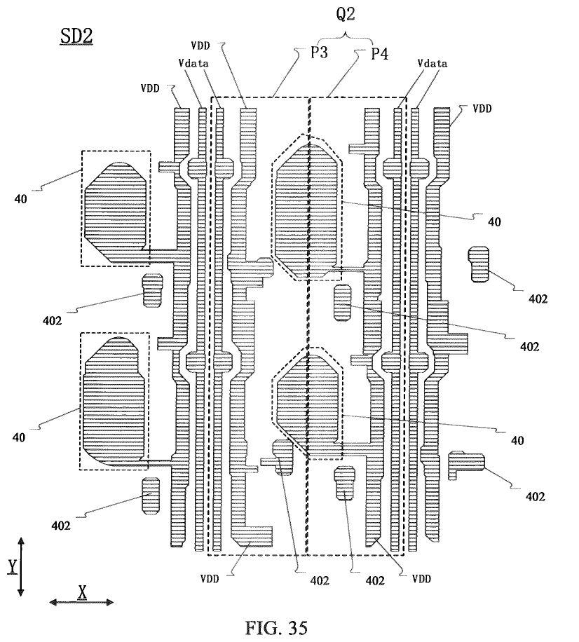

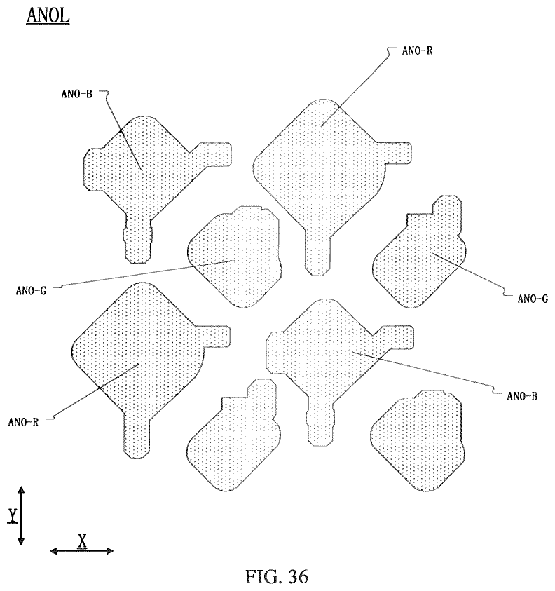

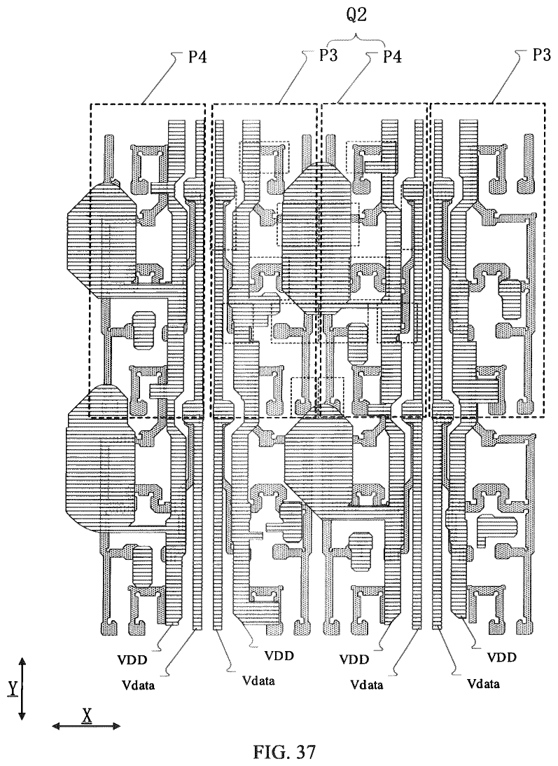

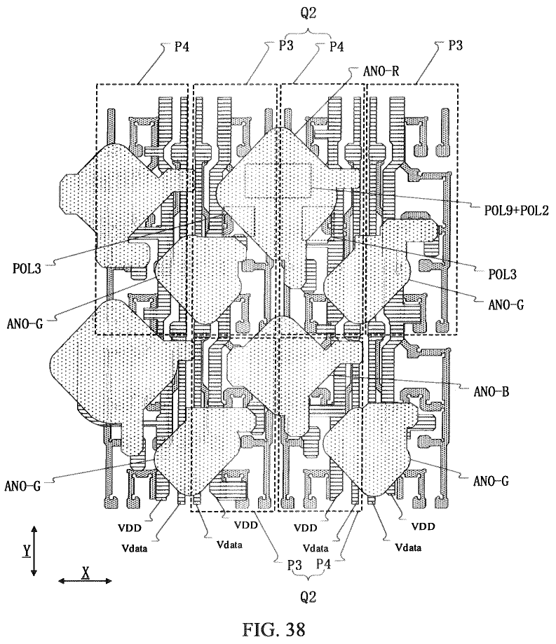

On the basis of the above embodiments, FIG. 29 is a structural layout of a display panel according to another embodiment of the present disclosure, FIG. 30 is a structural layout of the first metal layer in FIG. 29, FIG. 31 is a structural layout of the active layer in FIG. 29, FIG. 32 is a structural layout of the first conductive layer in FIG. 29, FIG. 33 is a structural layout of the second conductive layer in FIG. 29, FIG. 34 is a structural layout of the first source-drain metal layer in FIG. 29, FIG. 35 is a structural layout of the second source-drain metal layer in FIG. 29, FIG. 36 is a structural layout of the first electrode layer in FIG. 29, FIG. 37 is a stacked layout of the active layer and the second source-drain metal layer in FIG. 29, and FIG. 38 is a stacked layout of the active layer, the second source-drain metal layer and the first electrode layer in FIG. 29.

It is worth noting that in this exemplary embodiment, the first metal layer BSM, the active layer Polly, the first conductive layer Gate1, and the second conductive layer Gate2 can be mirror-symmetrical structures. Compared with the layout structure of FIG. 4, this exemplary embodiment only sets the pixel driving circuit(s) in mirror-symmetrical manner without changing the specific structure of transistors and capacitors in each pixel driving circuit. In other words, this exemplary embodiment may have the entire structure of the first metal layer BSM, the active layer Polly, the first conductive layer Gate1, and the second conductive layer Gate2 in the layout of FIG. 4, which will not be described in detail herein.

In this exemplary embodiment, the display panel may include a plurality of second repeating units Q2, each of which may include a third pixel driving circuit P3 and a fourth pixel driving circuit P4 adjacently arranged in the row direction X. In the same second repeating unit Q2, the third pixel driving circuit P3 and the fourth pixel driving circuit P4 are mirror-symmetrical, and any two second repeating units Q2 adjacent to each other in the row direction X are mirror images of each other. It should be understood that the pixel driving circuit includes a plurality of film layers, and therefore, when referring to that the third pixel driving circuit and the fourth pixel driving circuit are mirror images of each other in the present disclosure, it means that any film layer structure in the third pixel driving circuit has a one-to-one corresponding and mirror-symmetrical same film layer structure in the fourth pixel driving circuit.

Further, as shown in FIG. 34, in this exemplary embodiment, the first source-drain metal layer SD1 may also include a first connecting line 35, where the orthographic projection of the first connecting line 35 on the base substrate may extend along the column direction Y. The first connecting line 35 may connect the second bridge portion 32 in the pixel driving circuit of this row to the second bridge portion 32 in the pixel driving circuit of the next row, thereby connecting the second bridge portions 32 of respective pixel driving circuits in the first pixel column, so that the second initialization signal line Vinit2 may form a grid structure staggered in rows and columns. It can be understood that the second initialization signal line Vinit2 of the grid structure also has the beneficial effects described in the above embodiments, which will not be repeated here.

As shown in FIG. 35, in this exemplary embodiment, the second source-drain metal layer SD2 may include a data signal line Vdata, a first power line VDD, and an electrode planarization portion 40. Two data signal lines Vdata in the same repeating unit are mirror-symmetrical, and two first power lines VDD are mirror-symmetrical. Two pixel driving circuits in one second repeating unit Q2 may share one electrode planarization portion 40. Specifically, the electrode planarization portion 40 may be located in the middle of the second repeating unit Q2, so that two first power lines VDD and two data signal lines Vdata in the same repeating unit are both respectively located on the left and right sides of the electrode planarization portion 40.

As shown in FIG. 37, the orthographic projection of the electrode planarization portion 40 on the base substrate may at least partially overlap with the orthographic projections, on the base substrate, of two second active portions POL2, two third active portions POL3, and two ninth active portions POL9 in the same pixel driving circuit. For example, it may cover the orthographic projections, on the base substrate, of the second active portions POL2 and the ninth active portions POL9 in the two pixel driving circuits in the same second repeating unit Q2, and partially overlap with the orthographic projections of two third active portions POL3 on the base substrate, where the ratio of the overlapping area to the area of the third active portion POL3 can be 5%, such as 5%, 10%, 20%, 25%, 30%, 35%, 40%, 50%, 60%, 70%, or the like. In other words, the electrode planarization portion 40 can shield both the two second transistors T2 in the same repeating unit, and can symmetrically shield partial structures of the two driving transistors T3. In this exemplary embodiment, there is no need to additionally provide a shielding metal in the second source-drain metal layer SD2, so the light transmittance of the first display area 101 can be improved.

As shown in FIG. 38, in this exemplary embodiment, the first electrode ANO of the first electrode layer ANOL can be moved as a whole, so that in one second repeating unit Q2, one first electrode ANO can shield the second transistors T2 of two pixel driving circuits. As described above, the first electrodes ANO-B of the third sub-pixel B, the first sub-pixel R, and the second sub-pixel G in the same row are located in two sub-pixel rows. The first electrodes ANO-B of the third sub-pixel B and the first sub-pixel R in the first sub-pixel row X1 may be provided as being located above the electrode planarization portion 40 in the second repeating unit Q2 where they are located, that is, the first electrode ANO-R of the first sub-pixel R and the first electrode ANO-B of the third sub-pixel B are used to shield the second transistors T2 in the second repeating unit Q2 where they are located. In other words, the orthographic projection of the first electrode ANO located in the first sub-pixel row X1 on the base substrate can cover the orthographic projections of two second active portions POL2 and two ninth active portions POL9 in the repeating unit on the base substrate. In other words, the first electrode ANO-R of the first sub-pixel R and the first electrode ANO-B of the third sub-pixel B respectively shield the second transistors T2 of two pixel driving circuits in the repeating unit.

Continuing to refer to FIG. 38, the orthographic projection of the first electrode ANO in the first sub-pixel row X1 on the base substrate also at least partially overlaps with the orthographic projections, on the base substrate, of two third active portions POL3 in the repeating unit where it is located, where the ratio of the overlapping area to the area of the third active portion POL3 can be greater than or equal to 35%, such as 35%, 40%, 45%, 50%, 55%, 60%, 70%, 80%, or the like. In other words, the first electrode ANO-R of the first sub-pixel R and the first electrode ANO-B of the third sub-pixel B also partially shield two driving transistors T3 respectively in the repeating unit where they are located. Because the area of the first electrode ANO is larger than the area of the first planarization portion 411, the first electrode ANO can shield more structures of the driving transistor T3, thereby improving the shielding effect on the driving transistor T3, further enhancing the anti-interference performance of the display panel against strong light, and effectively mitigating the color deviation phenomenon of the display panel when exposed to strong light.

As shown in FIG. 34, in this exemplary embodiment, the first source-drain metal layer SD1 may include the first bridge portion 31, the second bridge portion 32, the third bridge portion 33 and the power adapter line VDDL extending along the column direction Y. One end of the first bridge portion 31 may be connected to the eleventh active portion POL11 through a via to connect the second electrode of the first transistor T1, and the other end of the first bridge portion 31 can be connected to the first conductive block 11 through a via, thereby connecting the second electrode of the first transistor T1 to the gate of the driving transistor T3. One end of the second bridge portion 32 may be connected to the fifteenth active portion POL 15 through a via to connect the first electrode of the seventh transistor T7, and the other end thereof may be connected to the second initialization signal line Vinit2 through a via, thereby connecting the first electrode of the seventh transistor T7 to the second initialization signal line Vinit2. One end of the third bridge portion 33 may be connected to the twelfth active portion POL12 through a via to connect the first electrode of the first transistor T1, and the other end thereof may be connected to the first initialization signal line Vinitl through a via, thereby connecting the first electrode of the first transistor T1 to the first initialization signal line Vinit1. The power adapter line VDDL may be connected to the seventeenth active portion POL 17 through a via to connect the first electrode of the fifth transistor T5. The power adapter line VDDL may also be connected to the first power line VDD of the second source-drain metal layer SD2 through a via, thereby connecting the first electrode of the fifth transistor T5 to the first power line VDD. In addition, the power adapter line VDDL may also be connected to the second conductive block 22 of the second conductive layer Gate2 through a via, thereby connecting the second electrode of the storage capacitor Cst to the first power line VDD. In this exemplary embodiment, the first bridge portions 31, the second bridge portions 32, the third bridge portions 33 and the power adapter lines VDDL in two pixel driving circuits of the same second repeating unit Q2 are all arranged in mirror symmetry.

As shown in FIG. 34, in this exemplary embodiment, the first source-drain metal layer SD1 further includes a data adapter portion VdataL, which may be connected with the fourteenth active portion POL14 and the data signal line Vdata through vias, respectively, thereby connecting the second electrode of the fourth transistor T4 to the data signal line Vdata.

As shown in FIG. 35, in this exemplary embodiment, the second source-drain metal layer SD2 may include a data signal line Vdata and a first power line VDD extending along the column direction Y, where the data signal line Vdata is connected to the data adapter part VdataL through a via. In two second adjacent repeating units Q2 in the row direction X, the data signal line Vdata in a third pixel driving circuit P3 is arranged adjacent to is a mirror image of the data signal line Vdata in a fourth pixel driving circuit of another repeating unit. In other words, in a second repeating unit Q2, the data signal line Vdata is close to the outermost side of the repeating unit. The first power line VDD may be connected to the power adapter line VDDL through a via. In two second repeating units Q2 adjacent in the row direction X, the first power line VDD in a third pixel driving circuit P3 and the first power line VDD in a fourth pixel driving circuit P4 of another repeating unit are respectively located on both sides of two data signal lines Vdata. In other words, in this exemplary embodiment, the data signal lines Vdata in two second repeating units Q2 adjacent to each other in the row direction X are arranged adjacently, and the first power lines VDD are located on both sides of two data signal lines Vdata. On this basis, the orthographic projection of the first electrode ANO located in the second sub-pixel row X2 on the base substrate is located on the orthographic projections, on the base substrate, of the first power lines VDD and the data signal lines Vdata in the two second repeating units Q2 adjacent to each other in the row direction X. In other words, the first electrode ANO of the second sub-pixel row X2 is planarized and supported by the data signal lines Vdata and the first power lines VDD in the two repeating units. In this way, there is no need to arrange any electrode planarization portion 40 below the second source-drain metal layer SD2 corresponding to the first electrode ANO in the second sub-pixel row X2, and the number of arranged metal planarization portions is reduced, thereby improving the light transmittance of the display panel and facilitating realization of a narrow frame of the display panel.

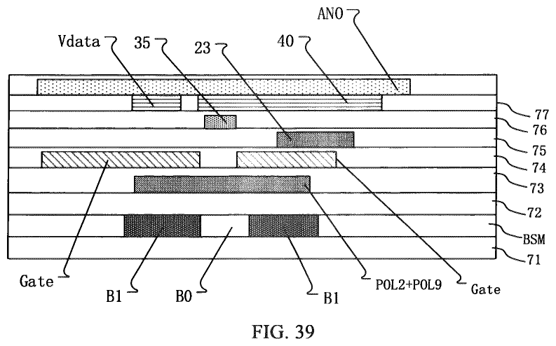

FIG. 39 is a cross-sectional view along the AA direction in FIG. 4, and the display panel may further include a buffer layer 72, a first insulating layer 73, a second insulating layer 74, a first dielectric layer 75, a passivation layer 77, and a second dielectric layer 77, where the base substrate 71, the metal shielding layer BSM, the buffer layer 72, the active layer Polly, the first insulating layer 73, the first conductive layer Gate1, the second insulating layer 74, the second conductive layer Gate2, the first dielectric layer 75, the first source-drain metal layer SD1, the passivation layer 76, the second dielectric layer 77, the second source-drain metal layer SD2, and the first electrode layer ANOL are stacked in sequence. The first insulating layer 73 may be an organic insulating layer, the second insulating layer 74 may be silicon oxide, the first dielectric layer 75 and the second dielectric layer 77 may be silicon nitride layers, and the materials of the passivation layer 77 and the buffer layer 72 may be silicon oxide, silicon nitride, or the like. The base substrate 71 may include a glass substrate, a barrier layer, and a polyimide layer stacked in sequence, where the barrier layer may be an inorganic material. The material of the first conductive layer Gate1 and the second conductive layer Gate2 may be one of molybdenum, aluminum, copper, titanium, niobium or an alloy thereof; a molybdenum/titanium alloy or laminate; or the like. The material of the first source-drain metal layer SD1 and the second source-drain metal layer SD2 may include a metal material, for example, one of molybdenum, aluminum, copper, titanium, niobium or an alloy thereof; or a molybdenum/titanium alloy or laminate, etc.; or a titanium/aluminum/titanium laminate.

It should be understood that the terms “first”, “second” and “third” etc. used in the present disclosure are only used as labels to distinguish the names of different structures, and are not intended to limit the quantity of their objects, nor do they have an order relationship.

The present disclosure further provides a display device, which includes the display panel according to any embodiment of the present disclosure

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. A display panel, comprising pixel driving circuit, wherein the pixel driving circuit comprises a second transistor and a driving transistor, a first electrode of the second transistor is connected to a gate of the driving transistor, and a second electrode of the second transistor is connected to a first electrode of the driving transistor; wherein the display panel further comprises:
a base substrate;
an active layer, located on a side of the base substrate, wherein the active layer comprises: a second active portion, configured to form a channel region of the second transistor; and
a third active portion, connected to the second active portion, wherein the third active portion is configured to form a channel region of the driving transistor;
a first metal layer, located between the base substrate and the active layer; and
a second metal layer, located on a side of the active layer away from the base substrate;
wherein orthographic projections of both the first metal layer and the second metal layer on the base substrate at least partially overlap with orthographic projections of the second active portion and the third active portion on the base substrate.

2. The display panel according to claim 1, wherein the first metal layer is connected to a constant voltage source; the second active portion comprises a first active sub-portion and a second active sub-portion; and
the active layer further comprises:
a ninth active portion, connected between the first active sub-portion and the second active sub-portion;
wherein the orthographic projection of the first metal layer on the base substrate does not overlap with an orthographic projection of the ninth active portion on the base substrate.

3. The display panel according to claim 2, wherein the display panel comprises a plurality of the pixel driving circuits, the first metal layer comprises a plurality of shielding units, with each of the shielding units corresponding to one of the pixel driving circuits;
the shielding unit comprises:
a first shielding portion, arranged corresponding to the second active portion, wherein the first shielding portion has a notch, an orthographic projection of the first shielding portion on the base substrate overlaps with the orthographic projection of the second active portion on the base substrate, and the orthographic projection of the ninth active portion on the base substrate is located within an orthographic projection of the notch on the base substrate; and
a second shielding portion, arranged corresponding to the third active portion and connected to the first shielding portion, wherein an orthographic projection of the second shielding portion on the base substrate overlaps with the orthographic projection of the third active portion on the base substrate.

4. The display panel according to claim 1, wherein the first metal layer is connected to a constant voltage source; the display panel comprises a plurality of the pixel driving circuits, the first metal layer comprises a plurality of shielding units, with each of the shielding units corresponding to one of the pixel driving circuits;
the shielding unit comprises:
a second shielding portion, arranged corresponding to the third active portion and connected to a first shielding portion, wherein an orthographic projection of the second shielding portion on the base substrate overlaps with the orthographic projection of the third active portion on the base substrate;
the display panel further comprises:
a first conductive layer, located on the side of the active layer away from the base substrate, and the first conductive layer comprises: a first conductive block, configured to form the gate of the driving transistor, wherein an orthographic projection of the first conductive block on the base substrate covers the orthographic projection of the third active portion on the base substrate and overlaps with the orthographic projection of the second shielding portion on the base substrate.

5. The display panel according to claim 4, wherein the orthographic projection of the first conductive block on the base substrate covers the orthographic projection of the second shielding portion on the base substrate; or
wherein the orthographic projection of the first conductive block on the base substrate coincides with the orthographic projection of the second shielding portion on the base substrate.

6. (canceled)

7. The display panel according to claim 1, wherein the first metal layer is connected to a constant voltage source; the display panel comprises a plurality of the pixel driving circuits, the first metal layer comprises a plurality of shielding units, with each of the shielding units corresponding to one of the pixel driving circuits;
the shielding unit comprises:
a first shielding portion, arranged corresponding to the second active portion, wherein the first shielding portion has a notch, an orthographic projection of the first shielding portion on the base substrate overlaps with the orthographic projection of the second active portion on the base substrate, and an orthographic projection of a ninth active portion on the base substrate is located within an orthographic projection of the notch on the base substrate;
a second shielding portion, arranged corresponding to the third active portion and connected to the first shielding portion, wherein an orthographic projection of the second shielding portion on the base substrate overlaps with the orthographic projection of the third active portion on the base substrate;
a first connecting portion, connected to the first shielding portion, wherein an orthographic projection of the first connecting portion on the base substrate extends along a column direction;
a second connecting portion, connected to a side, in the column direction, of the second shielding portion away from the first shielding portion, wherein an orthographic projection of the second connecting portion on the base substrate extends along the column direction;
a third connecting portion, connected to a side of the second shielding portion in a row direction, wherein an orthographic projection of the third connecting portion on the base substrate extends along the row direction; and
a fourth connecting portion, connected to a side, in the row direction, of the second shielding portion away from the third connecting portion, wherein an orthographic projection of the fourth connecting portion on the base substrate extends along the row direction;
wherein, in two adjacent shielding units in the row direction, the third connecting portion in one shielding unit is connected to the fourth connecting portion in the other shielding unit; and
in two adjacent shielding units in the column direction, the first connecting portion in one shielding unit is connected to the second connecting portion in the other shielding unit.

8. The display panel according to claim 7, wherein the pixel driving circuit further comprises a first transistor, and a second electrode of the first transistor is connected to the gate of the driving transistor;
the active layer further comprises:
a first active portion, configured to form a channel region of the first transistor, wherein the first active portion comprising a fifth active sub-portion and a sixth active sub-portion;
wherein, the first connecting portion comprises a first constituent part and a second constituent part, the first constituent part is connected between the first shielding portion and the second constituent part, an orthographic projection of the first constituent part on the base substrate extends along the row direction, an orthographic projection of the second constituent part on the base substrate extends along the column direction, and the orthographic projection of the second constituent part on the base substrate is located between orthographic projections of the fifth active sub-portion and the sixth active sub-portion on the base substrate.

9. The display panel according to claim 8, wherein the second connecting portion comprises a third constituent part, a fourth constituent part and a fifth constituent part, the fourth constituent part is connected between the third constituent part and the fifth constituent part, and orthographic projections of both the third constituent part and the fifth constituent part on the base substrate extend along the column direction and are staggered in the row direction;
in the two adjacent shielding units in the column direction, the fifth constituent part in one shielding unit of a current row is connected to the second constituent part in the other shielding unit of a next row.

10. The display panel according to claim 7, further comprising:
a second source-drain metal layer, located on a side of a first conductive layer away from the base substrate, and the second source-drain metal layer comprises:
a first power line, wherein an orthographic projection of the first power line on the base substrate extends along the column direction, and the first power line is connected to at least one of the first connecting portion, the second connecting portion, the third connecting portion and the fourth connecting portion in the first metal layer through a via in a non-display area of the display panel.

11. The display panel according to claim 1, wherein the second active portion comprises a first active sub-portion and a second active sub-portion; and the display panel further comprises:
a first conductive layer, located on the side of the active layer away from the base substrate, wherein the first conductive layer comprises:
a gate signal line, comprising a main extension portion and a secondary extension portion connected to a side of the main extension portion, wherein an orthographic projection of the main extension portion on the base substrate extends along a row direction and covers an orthographic projection of the first active sub-portion on the base substrate, an orthographic projection of the secondary extension portion on the base substrate extends along a column direction and covers an orthographic projection of the second active sub-portion on the base substrate, and the secondary extension portion and a partial structure of the main extension portion are configured to form a gate of the second transistor;
wherein, the first metal layer comprises a plurality of shielding units, with each of the shielding units corresponding to one pixel driving circuit, the shielding unit comprises a first shielding portion arranged corresponding to the second active portion, and an orthographic projection of the first shielding portion on the base substrate overlaps with the orthographic projection of the second active portion on the base substrate;
the first shielding portion comprises a first shielding sub-portion and a second shielding sub-portion, the first shielding sub-portion corresponds to the first active sub-portion, the second shielding sub-portion corresponds to the second active sub-portion, an orthographic projection of the first shielding sub-portion on the base substrate extends along the row direction and has a fifth width in the column direction, a first overlapping portion is formed between the orthographic projections of the main extension portion and the first shielding sub-portion on the base substrate and has a seventh width in the column direction, and the fifth width is greater than the seventh width;
an orthographic projection of the second shielding sub-portion on the base substrate extends along the column direction and has a sixth width in the row direction, a second overlapping portion is formed between the orthographic projections of the secondary extension portion and the second active sub-portion on the base substrate and has an eighth width in the row direction, and the sixth width is greater than the eighth width.

12. The display panel according to claim 11, wherein a ratio of the seventh width to the fifth width and a ratio of the eighth width to the sixth width are both greater than or equal to 50%; or
wherein the second overlapping portion has a first length in the column direction, and the orthographic projection of the secondary extension portion on the base substrate has a second length in the column direction, wherein the first length is smaller than the second length.

13. (canceled)

14. The display panel according to claim 1, further comprising:
a first electrode layer, located on the side of the active layer away from the base substrate, wherein the first electrode layer comprising a plurality of first electrodes, with each of the first electrodes corresponding to one pixel driving circuit;
wherein, the display panel comprises a first sub-pixel, a second sub-pixel and a third sub-pixel, with each sub-pixel corresponding to one pixel driving circuit, wherein a first electrode of the first sub-pixel and a first electrode of the third sub-pixel are located in a first pixel column, a first electrode of the second sub-pixel is located in a second pixel column, and the first pixel column and the second pixel column are alternately distributed in a row direction.

15. The display panel according to claim 14, wherein the second metal layer is the first electrode layer; the second active portion comprises a first active sub-portion and a second active sub-portion; and
the active layer further comprises:
a ninth active portion, connected between the first active sub-portion and the second active sub-portion;
wherein, an orthographic projection of at least part of the first electrodes on the base substrate covers orthographic projections of the second active portion, the third active portion and the ninth active portion on the base substrate.

16. The display panel according to claim 15, comprising a plurality of first repeating units arranged in an array along row and column directions, wherein the first repeating unit comprises a first pixel driving circuit and a second pixel driving circuit adjacently arranged in the row direction;
in any of the first repeating units, an orthographic projection, on the base substrate, of a first electrode connected to the first pixel driving circuit covers orthographic projections, on the base substrate, of the second active portion and the ninth active portion in the first pixel driving circuit, and partially overlaps with the orthographic projection of the third active portion on the base substrate; the orthographic projection, on the base substrate, of the first electrode connected to the first pixel driving circuit also at least partially overlaps with orthographic projections, on the base substrate, of the second active portion and the ninth active portion in the second pixel driving circuit; an orthographic projection, on the base substrate, of a first electrode connected to the second pixel driving circuit partially overlaps with an orthographic projection, on the base substrate, of the third active portion in the second pixel driving circuit.

17. The display panel according to claim 16, wherein, in any of the first repeating units, the orthographic projection, on the base substrate, of the first electrode connected to the first pixel driving circuit also covers the orthographic projection, on the base substrate, of the third active portion in the first pixel driving circuit and/or also covers the orthographic projections, on the base substrate, of the second active portion and the ninth active portion in the second pixel driving circuit; or
wherein the first sub-pixel and the third sub-pixel both correspond to the first pixel driving circuit, and the second sub-pixel corresponds to the second pixel driving circuit.

18. (canceled)

19. The display panel according to claim 15, wherein the ninth active portion comprises a third active sub-portion and a fourth active sub-portion, the third active sub-portion is connected to the first active sub-portion, and the fourth active sub-portion is connected to the second active sub-portion; the first electrodes in the first sub-pixel and the third sub-pixel each comprise a main portion and an additional portion, and the additional portion is connected to a side of the main portion along the row direction;
the display panel further comprises:
a first conductive layer, located between the active layer and the first electrode layer, wherein the first conductive layer comprises:
a gate signal line, comprising a main extension portion and a secondary extension portion, wherein an orthographic projection of the main extension portion on the base substrate extends along the row direction and covers an orthographic projection of the first active sub-portion on the base substrate, an orthographic projection of the secondary extension portion on the base substrate extends along a column direction and covers an orthographic projection of the second active sub-portion on the base substrate, and the secondary extension portion and a partial structure of the main extension portion are configured to form a gate of the second transistor;
wherein, the display panel comprises a plurality of first repeating units arranged in an array along the row and column directions, the first repeating unit comprises a first pixel driving circuit and a second pixel driving circuit adjacently arranged in the row direction, the first pixel driving circuit is located in a first pixel column, and the second pixel driving circuit is located in a second pixel column;
in a same first repeating unit, an orthographic projection, on the base substrate, of the main portion of the first electrode in the first sub-pixel covers the orthographic projections, on the base substrate, of the second active portion, the third active portion and the ninth active portion in the first pixel driving circuit, and also covers orthographic projections, on the base substrate, of the first active sub-portion and the third active sub-portion in the second pixel driving circuit; and an orthographic projection, on the base substrate, of the additional portion of the first electrode in the first sub-pixel covers orthographic projections, on the base substrate, of the second active sub-portion and the fourth active sub-portion in the second pixel driving circuit; and
in the same first repeating unit, an orthographic projection, on the base substrate, of the main portion of the first electrode in the third sub-pixel covers the orthographic projections, on the base substrate, of the second active portion and the ninth active portion in the first pixel driving circuit and at least partially overlaps with the orthographic projection of the third active portion on the base substrate, and an orthographic projection, on the base substrate, of the additional portion of the first electrode in the third sub-pixel covers orthographic projections, on the base substrate, of the second active sub-portion and the ninth active portion in the second pixel driving circuit and at least partially overlaps with the orthographic projection of the first active sub-portion on the base substrate.

20. The display panel according to claim 14, wherein the second metal layer is a second source-drain metal layer, and the second source-drain metal layer is located between the active layer and the first electrode layer;
the second source-drain metal layer comprises:
an electrode planarization portion, arranged corresponding to the first electrode of a corresponding sub-pixel, wherein an orthographic projection of the first electrode on the base substrate is located on an orthographic projection of the electrode planarization portion on the base substrate; the orthographic projection of the electrode planarization portion on the base substrate also at least partially overlaps with the orthographic projections, on the base substrate, of the second active portion and the third active portion in the same pixel driving circuit.

21-26. (canceled)

27. The display panel according to claim 14, wherein the display panel comprises a plurality of second repeating units arranged in an array along row and column directions, and the second repeating unit comprises a third pixel driving circuit and a fourth pixel driving circuit arranged adjacently in the row direction;
the display panel further comprises a first conductive layer and a second conductive layer stacked on the side of the active layer away from the base substrate;
wherein, in a same second repeating unit, structures of a first metal layer, an active layer, a first conductive layer and a second conductive layer in the third pixel driving circuit and structures of a first metal layer, an active layer, a first conductive layer and a second conductive layer in the fourth pixel driving circuit are arranged as mirror images of each other; and
in any two adjacent second repeating units in the row direction, structures of a first metal layer, an active layer, a first conductive layer and a second conductive layer in one second repeating unit and structures of a first metal layer, an active layer, a first conductive layer and a second conductive layer in another second repeating unit are arranged as mirror images of each other.

28-31. (canceled)

32. The display panel according to claim 1, wherein the pixel driving circuit comprises a seventh transistor, and a first electrode of the seventh transistor is connected to a second initialization signal terminal; the display panel comprises a first display area and a second display area at least partially surrounding the first display area, the first display area has a greater light transmittance than the second display area, and the first display area comprises a plurality of pixel rows;
the active layer further comprises:
a fifteenth active portion, configured to form the first electrode of the seventh transistor;
the display panel further comprises:
a second conductive layer, located between the active layer and the second metal layer,
wherein the second conductive layer comprises:
a second initialization signal line, wherein an orthographic projection of the second
initialization signal line on the base substrate extends along a row direction;
a first source-drain metal layer, located between the second conductive layer and the second metal layer, wherein the first source-drain metal layer comprises:
a second bridge portion, wherein an orthographic projection of the second bridge portion on the base substrate extends along a column direction, one end of the second bridge portion is connected to the fifteenth active portion through a via, and the other end of the second bridge portion is connected to the second initialization signal line through a via, thereby connecting the first electrode of the seventh transistor to the second initialization signal line; and
a first connecting line, located in the second display area, wherein an orthographic projection of the first connecting line on the base substrate extends along the column direction, and the first connecting line is connected to two second bridge portions of two adjacent rows.

33. A display device, comprising the display panel according to claim 1.
